(19) United States
(12) Patent Application Publication
(10) Pub. No.: US 2026/0164819 A1
(43) Pub. Date: Jun. 11, 2026

(54) RADIATION DETECTOR AND RADIATION IMAGING SYSTEM

(71) Applicant: CANON KABUSHIKI KAISHA, Tokyo (JP)

(72) Inventors: TATSUHITO GODEN, Tokyo (JP); TAKANORI WATANABE, Kanagawa (JP)

(21) Appl. No.: 19/394,332

(22) Filed: Nov. 19, 2025

(30) Foreign Application Priority Data
Dec. 11, 2024 (JP) 2024-217046

(51) Int. Cl. H10F 39/18; G01T 1/29; H10F 39/00

(52) U.S. Cl. CPC H10F 39/1895; G01T 1/2914; H10F 39/1892; H10F 39/811

(57) ABSTRACT

A radiation detector includes a first semiconductor chip including a detection region and a peripheral region positioned around the detection region in plan view, a support portion disposed in the peripheral region so as not to overlap the detection region in plan view, and a second semiconductor chip disposed in the peripheral region. In plan view, an end portion of the support portion, which is positioned on a side closer to the detection region among end portions of the support portion, is disposed closer to the detection region than an end portion of the second semiconductor chip, which is positioned on a side closer to an outer edge of the first semiconductor chip among end portions of the second semiconductor chip.

### BACKGROUND

### Field of the Technology

The present disclosure relates to a radiation detector and the like.

### Description of the Related Art

A radiation detector that obtains a radiation image by receiving radiation with a semiconductor element such as a complementary metal-oxide-semiconductor (CMOS) image sensor without using a scintillator (wavelength converter) has been known. In such a radiation detector, when radiation enters a deep portion of the semiconductor element, crosstalk or secondary electrons are generated, which results in a decrease in detection accuracy, and therefore, a semiconductor substrate is thinned. When the semiconductor substrate, which is a base of the semiconductor element, is thinned, a mechanical strength of the semiconductor substrate is decreased.

JP 2019-87640 A discloses a detector in which a thickness of a semiconductor layer in at least a part of a detection region where an energy ray is detected is smaller than a thickness of a peripheral region. It is described that, in the detection region of the semiconductor layer, a plurality of grooves are provided on a back surface that is opposite to a surface on which the energy ray is incident to reduce crosstalk between pixels. In addition, it is described that a strength is ensured by holding the thin semiconductor layer with the thick peripheral region, and a configuration in which a support portion formed by the semiconductor substrate is bonded to the peripheral region in order to increase the thickness of the peripheral region is disclosed. By forming the semiconductor element such as a metal-oxide-semiconductor (MOS) transistor on the support portion, a part of a peripheral circuit can be provided on the support portion, and the detector can be downsized.

Meanwhile, a technology of stacking (disposing) a semiconductor chip on another semiconductor chip is known. By stacking a small semiconductor chip manufactured by a high-definition process on another semiconductor chip, an integration rate of the semiconductor elements can be increased and a manufacturing cost can be reduced. When the semiconductor chip is improved in performance and functionality, an amount of heat generation tends to be increased due to an increase in operation speed and an increase in circuit integration. When such a semiconductor chip is stacked on another semiconductor chip having a radiation detection region, heat of the semiconductor chip may be conducted to the detection region and increase a temperature of a detection element. When the temperature of the detection element is increased, noise is increased due to an increase in dark current, which may degrade performance of the radiation detector. Therefore, in order to improve a degradation resistance of the radiation detector, it is important to suppress a temperature rise of the detection element.

Therefore, in order to achieve high detection performance with suppressed noise in a radiation detector, a technology advantageous for efficiently dissipating heat from stacked semiconductor chips has been expected.

### SUMMARY

According to a first aspect of the present disclosure, a radiation detector includes a first semiconductor chip including a detection region and a peripheral region positioned around the detection region in plan view, a support portion disposed in the peripheral region so as not to overlap the detection region in plan view, and a second semiconductor chip disposed in the peripheral region. In plan view, an end portion of the support portion, which is positioned on a side closer to the detection region among end portions of the support portion, is disposed closer to the detection region than an end portion of the second semiconductor chip, which is positioned on a side closer to an outer edge of the first semiconductor chip among end portions of the second semiconductor chip.

Features of the present disclosure will become apparent from the following description of embodiments with reference to the attached drawings. The following description of embodiments is described by way of example.

### BRIEF DESCRIPTION OF THE DRAWINGS

FIG. 1A is a cross-sectional view of a radiation detector according to a first embodiment.

FIG. 1B is a plan view of the radiation detector according to the first embodiment when viewed in plan from above.

FIG. 2 is a partial cross-sectional view illustrating a part of a radiation detection system in order to describe an attachment portion of the radiation detector.

FIG. 3 is a cross-sectional view illustrating a layer configuration of a detection region of the radiation detector according to the first embodiment.

FIG. 4 is an enlarged cross-sectional view illustrating a portion where a second semiconductor chip is mounted on a first semiconductor chip in a peripheral region of the radiation detector according to the first embodiment.

FIG. 5A is a view illustrating a mesh shape of a conductor layer included in a heat dissipation wiring in plan view.

FIG. 5B is a view illustrating a stripe shape of the conductor layer included in the heat dissipation wiring in plan view.

FIG. 6A is a view illustrating a manufacturing process (A) for the radiation detector according to the first embodiment.

FIG. 6B is a view illustrating a manufacturing process (B) for the radiation detector according to the first embodiment.

FIG. 6C is a view illustrating a manufacturing process (C) for the radiation detector according to the first embodiment.

FIG. 6D is a view illustrating a manufacturing process (D) for the radiation detector according to the first embodiment.

FIG. 7E is a view illustrating a manufacturing process (E) for the radiation detector according to the first embodiment.

FIG. 7F is a view illustrating a manufacturing process (F) for the radiation detector according to the first embodiment.

FIG. 7G is a view illustrating a manufacturing process (G) for the radiation detector according to the first embodiment.

FIG. 7H is a view illustrating a manufacturing process (H) for the radiation detector according to the first embodiment.

FIG. 8 is an enlarged cross-sectional view illustrating a portion where a second semiconductor chip is mounted on a first semiconductor chip in a peripheral region in a second embodiment.

FIG. 9 is an enlarged cross-sectional view illustrating a portion where a second semiconductor chip is mounted on a first semiconductor chip in a peripheral region in a third embodiment.

FIG. 10 is a plan view illustrating arrangement of members in a radiation detector according to a fourth embodiment.

FIG. 11 is a plan view illustrating arrangement of members in a radiation detector according to a fifth embodiment.

FIG. 12A is a cross-sectional view of a radiation detector according to a sixth embodiment.

FIG. 12B is a plan view of the radiation detector according to the sixth embodiment when viewed in plan from above.

FIG. 13A is a view illustrating a manufacturing process (A) for the radiation detector according to the sixth embodiment.

FIG. 13B is a view illustrating a manufacturing process (B) for the radiation detector according to the sixth embodiment.

FIG. 13C is a view illustrating a manufacturing process (C) for the radiation detector according to the sixth embodiment.

FIG. 13D is a view illustrating a manufacturing process (D) for the radiation detector according to the sixth embodiment.

FIG. 14E is a view illustrating a manufacturing process (E) for the radiation detector according to the sixth embodiment.

FIG. 14F is a view illustrating a manufacturing process (F) for the radiation detector according to the sixth embodiment.

FIG. 14G is a view illustrating a manufacturing process (G) for the radiation detector according to the sixth embodiment.

FIG. 14H is a view illustrating a manufacturing process (H) for the radiation detector according to the sixth embodiment.

FIG. 15A is a cross-sectional view of a radiation detector according to a seventh embodiment.

FIG. 15B is a plan view of the radiation detector according to the seventh embodiment when viewed in plan from above.

FIG. 16 is an enlarged cross-sectional view illustrating a portion where a second semiconductor chip is mounted on a first semiconductor chip in a peripheral region of the radiation detector according to the seventh embodiment.

FIG. 17A is a cross-sectional view of a radiation detector according to an eighth embodiment.

FIG. 17B is a plan view of the radiation detector according to the eighth embodiment when viewed in plan from above.

FIG. 18A is a cross-sectional view of a radiation detector according to a ninth embodiment.

FIG. 18B is a plan view of the radiation detector according to the ninth embodiment when viewed in plan from above.

FIG. 19A is a view illustrating a manufacturing process (A) for the radiation detector according to the ninth embodiment.

FIG. 19B is a view illustrating a manufacturing process (B) for the radiation detector according to the ninth embodiment.

FIG. 19C is a view illustrating a manufacturing process (C) for the radiation detector according to the ninth embodiment.

FIG. 19D is a view illustrating a manufacturing process (D) for the radiation detector according to the ninth embodiment.

FIG. 20E is a view illustrating a manufacturing process (E) for the radiation detector according to the ninth embodiment.

FIG. 20F is a view illustrating a manufacturing process (F) for the radiation detector according to the ninth embodiment.

FIG. 20G is a view illustrating a manufacturing process (G) for the radiation detector according to the ninth embodiment.

FIG. 21H is a view illustrating a manufacturing process (H) for the radiation detector according to the ninth embodiment.

FIG. 21I is a view illustrating a manufacturing process (I) for the radiation detector according to the ninth embodiment.

FIG. 21J is a view illustrating a manufacturing process (J) for the radiation detector according to the ninth embodiment.

FIG. 22K is a view illustrating a manufacturing process (K) for the radiation detector according to the ninth embodiment.

FIG. 22L is a view illustrating a manufacturing process (L) for the radiation detector according to the ninth embodiment.

FIG. 23A is a cross-sectional view of a radiation detector according to a tenth embodiment.

FIG. 23B is a plan view of the radiation detector according to the tenth embodiment when viewed in plan from above.

FIG. 24A is a view illustrating a manufacturing process (A) for a radiation detector according to an eleventh embodiment.

FIG. 24B is a view illustrating a manufacturing process (B) for the radiation detector according to the eleventh embodiment.

FIG. 24C is a view illustrating a manufacturing process (C) for the radiation detector according to the eleventh embodiment.

FIG. 25D is a view illustrating a manufacturing process (D) for the radiation detector according to the eleventh embodiment.

FIG. 25E is a view illustrating a manufacturing process (E) for the radiation detector according to the eleventh embodiment.

FIG. 25F is a view illustrating a manufacturing process (F) for the radiation detector according to the eleventh embodiment.

FIG. 26G is a view illustrating a manufacturing process (G) for the radiation detector according to the eleventh embodiment.

FIG. 26H is a view illustrating a manufacturing process (H) for the radiation detector according to the eleventh embodiment.

FIG. 26I is a view illustrating a manufacturing process (I) for the radiation detector according to the eleventh embodiment.

FIG. 27 is a diagram illustrating a configuration of a radiation imaging system according to a twelfth embodiment.

FIG. 28A is a diagram illustrating a configuration of a detection system according to a thirteenth embodiment.

FIG. 28B is a diagram illustrating a configuration of a transmission electron microscope according to the thirteenth embodiment.

### DESCRIPTION OF THE EMBODIMENTS

A radiation detector, a radiation imaging system, and the like according to embodiments of the present disclosure will be described with reference to the drawings. The embodiments described below are merely examples, and for example, detailed configurations can be appropriately changed and implemented by those skilled in the art without departing from the gist of the present disclosure.

In the drawings referred to in the following embodiments and description, elements denoted by the same reference signs have similar functions unless otherwise specified. In the drawings, in a case where a plurality of the same elements are arranged, reference signs and a description thereof may be omitted.

In addition, the drawings may be schematic for convenience of illustration and description, and thus, the shape, size, arrangement, and the like of elements in the drawings may not strictly match those of actual ones. In addition, “XX or more and YY or less” or “XX to YY” representing a numerical range means a numerical range including end points XX (lower limit) and YY (upper limit) unless otherwise specified. When numerical ranges are described in stages, the upper limit and the lower limit of each numerical range can be arbitrarily combined.

A state in which a semiconductor layer or a semiconductor chip is observed from a direction perpendicular to a principal surface thereof may be referred to as a state in which the semiconductor layer or the semiconductor chip is viewed in plan. In addition, a state in which not only the appearance of the semiconductor layer or the semiconductor chip but also the interior of the semiconductor layer or the semiconductor chip is viewed in a see-through manner from a direction perpendicular to the principal surface thereof may also be referred to as the state in which the semiconductor layer or the semiconductor chip is viewed in plan.

### First Embodiment

### Basic Configuration of Radiation Detector

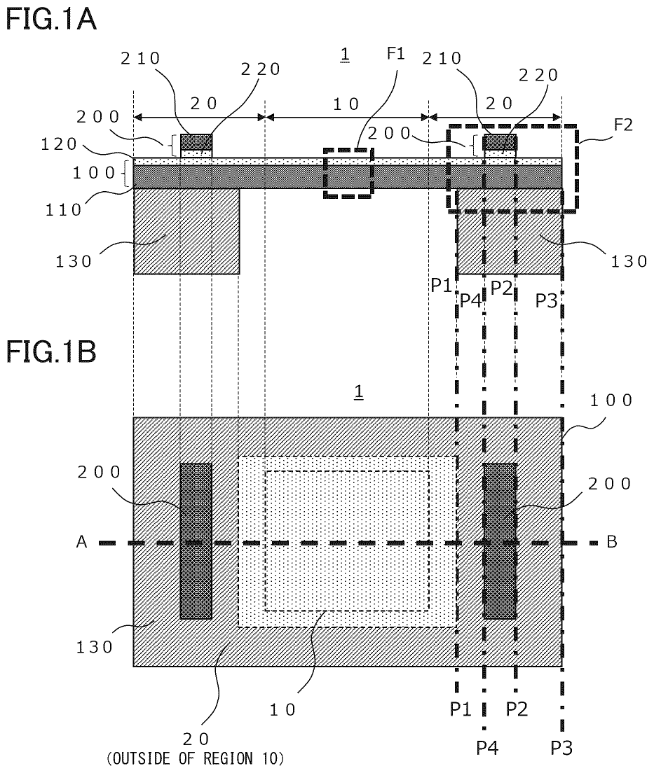

FIG. 1A is a cross-sectional view of a radiation detector 1 according to the first embodiment, and FIG. 1B is a plan view of the radiation detector 1 when viewed in plan from above. FIG. 1A corresponds to a cross-sectional view taken along line A-B of FIG. 1B.

As illustrated, the radiation detector 1 includes a first semiconductor chip 100, and the first semiconductor chip 100 includes a detection region 10 for detecting radiation and a peripheral region 20 positioned around the detection region 10. In FIG. 1B, a region inside a range schematically surrounded by a broken line is the detection region 10, and a region outside the range surrounded by the broken line is the peripheral region 20.

In the detection region 10, a plurality of pixels for detecting radiation and converting the radiation into a signal are disposed, and each pixel includes a reading circuit for outputting a detection signal. In the peripheral region 20, a drive circuit for driving the reading circuit included in the detection region 10, a signal processing circuit that processes a signal output from the reading circuit of the detection region 10, an output circuit that converts a signal into a predetermined format and outputs the signal, an external connection terminal, and the like are disposed. The external connection terminal is connected to an external electric circuit, power or a control signal is input from the outside to the first semiconductor chip 100 via the external connection terminal, and an output signal such as the detection signal is output from the first semiconductor chip 100 to the outside.

As illustrated in FIG. 1A, the first semiconductor chip 100 includes a semiconductor layer 110 and a wiring layer 120 stacked on the semiconductor layer 110. For the semiconductor layer 110, for example, a semiconductor material such as silicon or germanium is used. By thinning the semiconductor layer 110, scattering of radiation applied to the detection region 10 to the plurality of pixels is reduced, and a resolution of an obtained image is improved. A thickness of the first semiconductor chip 100 substantially corresponds to the sum of thicknesses of the semiconductor layer 110 and the wiring layer 120, and is, for example, 1 μm or more and 1000 μm or less, typically more than 10 μm and less than 100 μm, preferably 25 μm or more and 75 μm or less.

In addition, a second semiconductor chip 200 is disposed in the peripheral region 20 of the first semiconductor chip 100, and the first semiconductor chip 100 and the second semiconductor chip 200 are electrically connected to each other. The second semiconductor chip 200 includes a semiconductor layer 210 and a wiring layer 220 stacked on the semiconductor layer 210. A signal processing circuit that processes the detection signal output from the first semiconductor chip 100, a control circuit that generates a control signal to be supplied to the drive circuit mounted on the first semiconductor chip 100, and the like are mounted on the second semiconductor chip 200.

In the present embodiment, the wiring layer 120 of the first semiconductor chip 100 and the wiring layer 220 of the second semiconductor chip 200 are disposed so as to face each other. A bump connection structure or a Cu—Cu hybrid bonding structure described below can be implemented with such disposition, so that electrical connection between the first semiconductor chip 100 and the second semiconductor chip 200 can be easily achieved.

The second semiconductor chip 200 is preferably thinned in advance before being mounted on the first semiconductor chip 100. A thickness of the second semiconductor chip 200 substantially corresponds to the sum of thicknesses of the semiconductor layer 210 and the wiring layer 220, and is, for example, 1 μm or more and 1000 μm or less, typically more than 5 μm and less than 100 μm, preferably 10 μm or more and 50 μm or less.

As illustrated in FIG. 1B, the second semiconductor chips 200 are disposed respectively along a set of sides of the first semiconductor chip 100, the sides being arranged such that the detection region 10 interposed therebetween in plan view. Preferably, a plurality of second semiconductor chips 200 can be disposed at symmetrical positions about the detection region 10.

With such a configuration, heat generated by the second semiconductor chips 200 is symmetrically conducted from both sides to the center of the detection region 10, so that a local uneven heat distribution is less likely to occur, and a temperature distribution in the detection region 10 is reduced. As a result, a fluctuation in characteristic variation (a change in dark current) due to a temperature difference between the pixels is suppressed, and quality of a detection image is improved.

A support portion 130 for supporting the thinned first semiconductor chip 100 is attached to the peripheral region 20 of the first semiconductor chip 100, and a mechanical strength of the radiation detector is enhanced by the support portion 130. A material of the support portion 130 may be a semiconductor, an insulator, or a conductor as long as the material has a sufficient stiffness to support the semiconductor layer 110, and is preferably the same type of semiconductor material as the semiconductor layer 110 in order to reduce a stress (for example, a thermal stress) between the semiconductor layer 110 and the support portion 130. For example, if the semiconductor layer 110 is a silicon layer, the support portion 130 is preferably made of silicon, and if the semiconductor layer 110 is a germanium layer, the support portion 130 is preferably made of germanium. In a case where the support portion 130 is formed of a semiconductor, the semiconductor layer 110 and the support portion 130 may be a semiconductor single crystal having a continuous crystal structure between the semiconductor layer 110 and the support portion 130.

A thickness of the peripheral region 20 substantially corresponds to the sum of thicknesses of the first semiconductor chip 100 and the support portion 130. For example, the thickness of the peripheral region 20 is 10 μm or more and 10000 μm (10 mm) or less, typically 100 μm or more and 5000 μm or less, and preferably 200 μm or more and 1000 μm or less.

As illustrated in FIG. 1A or 1B, the support portion 130 is disposed in the peripheral region 20 so as not to overlap the detection region 10 in plan view. Specifically, the support portion 130 includes an opening portion at a position corresponding to the detection region 10 in plan view, and is disposed in the peripheral region 20 in a shape surrounding the detection region 10. FIG. 1B is a plan view when viewed in plan from above, but the support portion 130 is viewed in a see-through manner for easy understanding of the position where the support portion 130 is disposed. With such a configuration, the mechanical strength of the radiation detector can be secured even when the thinned first semiconductor chip 100 is used.

In the present embodiment, as illustrated in FIG. 1A, the second semiconductor chip 200 and the support portion 130 are respectively disposed on principal surfaces of the first semiconductor chip 100 on opposite sides in the peripheral region 20. It can also be said that the second semiconductor chip 200 and the support portion 130 are disposed so as to face each other with the first semiconductor chip 100 interposed therebetween.

A positional relationship between the second semiconductor chip 200 and the support portion 130 will be described in more detail. In the cross-sectional view of FIG. 1A and the plan view of FIG. 1B, lines P1 to P4 with alternating long and short dashes are illustrated in order to facilitate understanding of a correspondence relationship between positions in both drawings. P1 indicates a position of an end portion of the support portion 130, the end portion being on a side closer to the detection region 10 (detection region side) among end portions of the support portion 130. P2 indicates a position of an end portion of the second semiconductor chip 200, the end portion being on a side farther from the detection region 10 (in other words, an end portion closer to an outer edge of the first semiconductor chip 100). P3 indicates a position of an end portion of the support portion 130 on an outer edge side (in other words, a side of the first semiconductor chip 100 that is farther from the detection region 10). P4 indicates a position of an end portion of the second semiconductor chip 200, the end portion being on a side closer to the detection region 10 (in other words, an end portion farther from the outer edge of the first semiconductor chip 100).

The end portion (P1) of the support portion 130 on the side closer to the detection region 10 is disposed closer to the detection region 10 than the end portion (P2) of the second semiconductor chip 200 on the side closer to the outer edge. In addition, the end portion (P3) of the support portion 130 on the side closer to the outer edge is disposed closer to the outer edge of the first semiconductor chip 100 than the end portion (P4) of the second semiconductor chip 200 on the side closer to the detection region 10 is.

With a configuration in which at least a part of the support portion 130 and the second semiconductor chip 200 overlap each other in plan view, the heat of the second semiconductor chip 200 can be efficiently dissipated to the support portion 130. Since the heat of the second semiconductor chip 200 is efficiently dissipated via the support portion 130, the heat conducted from the second semiconductor chip 200 to the detection region 10 of the first semiconductor chip 100 is reduced, and noise such as the dark current generated in the detection region 10 is reduced.

### Attachment Portion of Radiation Detector

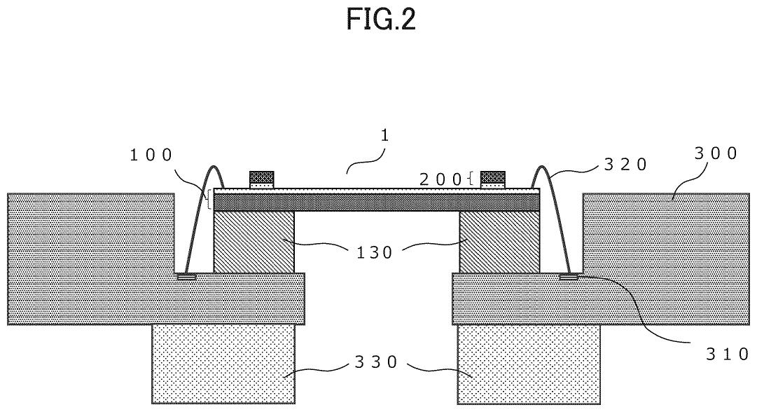

An example of a structure applied when the radiation detector 1 according to the present embodiment is attached to a radiation detection system will be described. FIG. 2 is a partial cross-sectional view illustrating a cross section of a part of the radiation detection system in order to describe a structure of an attachment portion of the radiation detector 1. In the radiation detection system, the entire range illustrated in FIG. 2 may be treated as the radiation detector in some cases.

When attaching the radiation detector 1 to the radiation detection system, the support portion 130 is disposed so as to be in contact with an attachment substrate 300. By fixing the support portion 130 to the attachment substrate 300, the first semiconductor chip 100 and the second semiconductor chip 200 are held and fixed to the radiation detection system.

The attachment substrate 300 includes wirings such as a power supply wiring and a signal wiring, and an external connection terminal 310 for electrically connecting the wirings to the outside. The external connection terminal 310 and the first semiconductor chip 100 are electrically connected to each other via a wire 320. A connection portion between the wire 320 and the first semiconductor chip 100 is described below. A driving signal and power are input to the radiation detector 1 via the wire 320, and a signal related to a radiation detection result is output from the radiation detector 1 to the attachment substrate 300.

A cooling mechanism 330 is connected to the attachment substrate 300, and the attachment substrate 300 is preferably connected to the cooling mechanism 330 via thermal grease or a heat conductive sheet. As the cooling mechanism 330, for example, a Peltier element or a member having a high thermal conductivity is used, but other cooling units can also be applied. The first semiconductor chip 100 and the second semiconductor chip 200 are cooled by the cooling mechanism 330 via the attachment substrate 300 and the support portion 130. A printed circuit board is generally used as the attachment substrate 300, and a substrate material having a high thermal conductivity is preferably used. Examples of the substrate material having a high thermal conductivity include a ceramic material such as alumina. In addition, a metal heat dissipation via may be formed in the attachment substrate 300.

Since the attachment substrate 300 can function as an adapter for connecting the radiation detector 1 and the cooling mechanism 330, the use of the attachment substrate 300 increases the degree of mechanical design freedom in attachment to the radiation detection system. In addition, various electric components such as a capacitor and a connector can be mounted on the attachment substrate 300. By stably supplying a power supply voltage using a capacitor, it is possible to suppress mixing of power supply noise into the radiation detector 1. In addition, by connecting the attachment substrate 300 to an external apparatus by a detachable connector (not illustrated), it becomes easy to attach and detach the radiation detector 1 to and from the radiation detection system and to replace the radiation detector 1.

### Detection Region of Radiation Detector

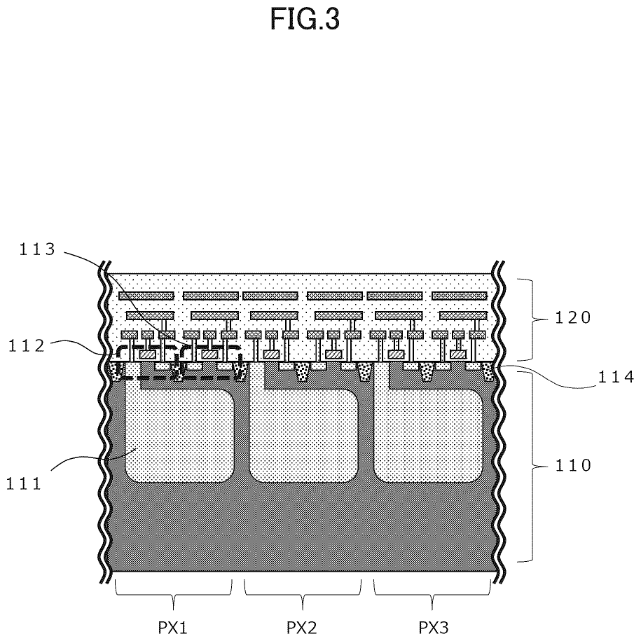

The detection region 10 included in the radiation detector 1 will be described. FIG. 3 is an enlarged cross-sectional view illustrating a part of the detection region 10, that is, a portion F1 surrounded by a broken line in FIG. 1A, in order to describe an example of a layer configuration of the detection region 10.

In the detection region 10, the semiconductor layer 110 is provided with a plurality of detection units 111 that detect radiation entering the semiconductor layer 110 and the reading circuit that reads the detection signal of the detection unit. The detection unit 111 has, for example, a diode structure, and collects electrons generated by the radiation at a cathode of a diode or collects holes at an anode of the diode. In addition, a control unit 112 including a reset circuit that resets electric charges of the detection unit 111 generated by radiation is provided. The detection region 10 is provided with an output unit 113 that outputs a signal based on a detection level of the detection unit 111. The output unit 113 can be implemented by, for example, a source follower circuit.

The reading circuit including the control unit 112 and the output unit 113 is implemented by a plurality of MOS transistors. In the detection region 10, the detection unit 111 and the reading circuit are arranged in a matrix. The MOS transistors of the reading circuit are separated from each other by an element separator 114 having a shallow trench isolation (STI) structure or a local oxidation of silicon (LOCOS) structure.

As indicated by a pixel PX1, a pixel PX2, and a pixel PX3 in FIG. 3, the plurality of pixels each including at least one detection unit 111 are arranged in a matrix in the detection region 10. Each of the pixel PX1, the pixel PX2, and the pixel PX3 includes the control unit 112 and the output unit 113. However, the output unit 113 may be shared by the plurality of pixels.

### Mounting of Second Semiconductor Chip

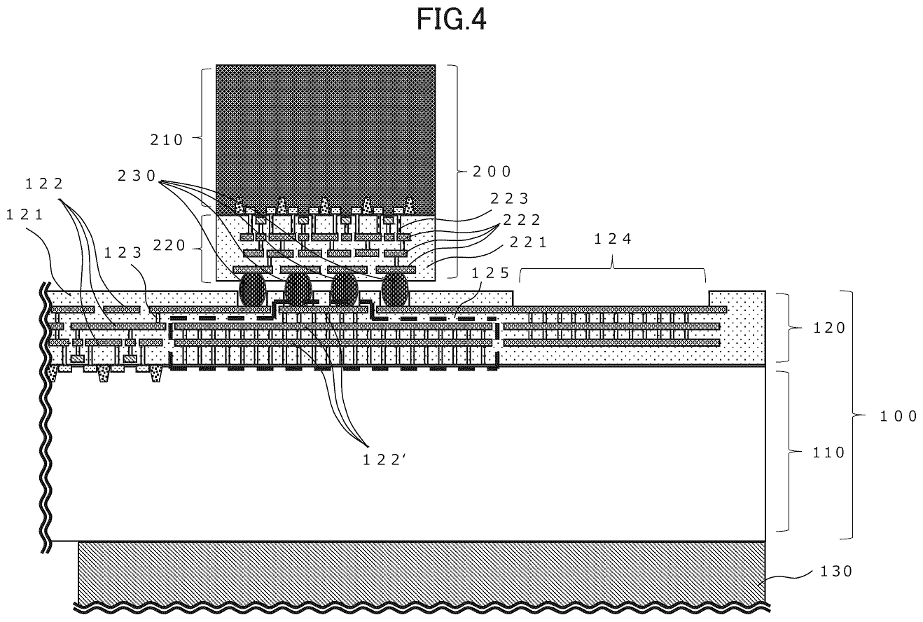

A structure of a portion where the second semiconductor chip 200 is disposed (stacked) on the first semiconductor chip 100 in the radiation detector 1 will be described. FIG. 4 is an enlarged cross-sectional view illustrating a portion where the second semiconductor chip 200 is stacked on the first semiconductor chip 100 in the peripheral region 20, that is, a portion F2 surrounded by a broken line in FIG. 1A.

The first semiconductor chip 100 includes the wiring layer 120 stacked on the semiconductor layer 110. The wiring layer 120 includes a plurality of conductor layers 122 insulated by an interlayer insulating film 121. Each of the plurality of conductor layers 122 is a part of a wiring included in a signal line, a power supply line, or the like included in the drive circuit.

A conductive member 123 that is a via plug is disposed in a via hole provided at a predetermined position in the interlayer insulating film 121, and the plurality of conductor layers 122 are electrically connected to each other by the conductive member 123. A protective film may be provided on a surface (uppermost layer) of the wiring layer 120. As the protective film, an insulator film made of an inorganic insulating material, such as a silicon oxide film, a silicon nitride film, a silicon carbide film, or a metal oxide film, is used. In the peripheral region 20, the external connection terminal 124, that is, a portion where the insulating film on the wiring layer 120 is partially removed and a part of the conductor layer 122 is exposed, is disposed. The wire 320 illustrated in FIG. 2 is connected to the external connection terminal 124 provided in the first semiconductor chip 100.

The second semiconductor chip 200 includes the semiconductor layer 210 and the wiring layer 220 stacked on the semiconductor layer 210. The wiring layer 220 includes a plurality of conductor layers 222 insulated by an interlayer insulating film 221. Each of the plurality of conductor layers 222 is a part of a wiring included in a signal processing circuit or a control circuit.

A conductive member 223 that is a via plug is disposed in a via hole provided at a predetermined position in the interlayer insulating film 221, and the plurality of conductor layers 222 are electrically connected to each other by the conductive member 223. A protective film similar to that of the first semiconductor chip 100 may be provided on a surface of the wiring layer 220.

The first semiconductor chip 100 and the second semiconductor chip 200 are electrically connected to each other via a bump 230. For example, a part of the conductor layer 122 of the outermost layer of the first semiconductor chip 100 and a part of the conductor layer 222 of the outermost layer of the second semiconductor chip 200 are exposed, the exposed portions are disposed to face each other, and both of the exposed portions are connected by a bump using metal plating or solder.

When the radiation detector 1 is viewed in plan, a heat dissipation structure for easily dissipating the heat of the second semiconductor chip 200 may be provided at a position where the second semiconductor chip 200 and the support portion 130 overlap each other. In FIG. 4, an example of the heat dissipation structure is illustrated as a portion surrounded by a broken line. In this example, a heat dissipation wiring 125 is provided as the heat dissipation structure.

The heat dissipation wiring 125 is disposed near the second semiconductor chip 200 and the support portion 130 in the first semiconductor chip 100. The heat dissipation wiring 125 includes a conductor layer 122′made of a metal material having a high thermal conductivity. The heat of the second semiconductor chip 200 is easily and efficiently conducted to the support portion 130 via the heat dissipation wiring 125 including the conductor layer 122′, so that heat dissipation efficiency of the radiation detector 1 is improved.

The heat dissipation wiring 125 may be implemented by coupling a plurality of conductor layers 122′ with a via plug. If the conductor layers 122′ are disposed in an empty space where the power supply wiring and the signal wiring are not disposed, and are coupled by a via plug, a thermal conductance of the heat dissipation wiring 125 can be increased. By increasing a size of a region where the heat dissipation wiring 125 and the second semiconductor chip 200 overlap each other in plan view, the heat of the second semiconductor chip 200 is easily efficiently conducted to the heat dissipation wiring 125 of the first semiconductor chip 100.

In addition, the conductor layer 122′ included in the heat dissipation wiring 125 is preferably connected to the semiconductor layer 110 by a via plug. Since the via plug is made of a metal material having a high thermal conductivity, the heat of the heat dissipation wiring 125 is easily conducted to the semiconductor layer 110. The support portion 130 is connected to the semiconductor layer 110, and the heat of the heat dissipation wiring 125 is easily dissipated to the support portion 130 via the semiconductor layer 110. If the support portion 130 is cooled, the semiconductor layer 110 is cooled, so that the heat of the heat dissipation wiring 125 is efficiently dissipated.

As a material of the via plug, for example, tungsten is used, and a thermal conductivity thereof is about 170 W/(m·K) at room temperature. For example, silicon oxide is used as the interlayer insulating film 121, and a thermal conductivity thereof is about 1.38 W/(m·K). Therefore, the heat dissipation wiring 125 is connected to the semiconductor layer 110 by the via plug, so that the heat of the heat dissipation wiring 125 is more easily conducted to the semiconductor layer 110 by about 100 times.

It is preferable that the heat dissipation wiring 125 is connected to a part of the conductor layer 222 included in the second semiconductor chip 200 via the bump 230. This is because the heat of the second semiconductor chip 200 is easily conducted to the heat dissipation wiring 125. The bump 230 is formed by, for example, plating, and a metal such as copper, nickel, gold, or tin, or a combination of these metals is used as a material of the bump 230. A thermal conductivity at room temperature is about 400 W/(m·K) for copper, about 90 W/(m·K) for nickel, about 300 W/(m·K) for gold, and about 65 W/(m·K) for tin. When not connected by the bump 230, the heat of the second semiconductor chip 200 is conducted to the heat dissipation wiring 125 via the interlayer insulating film 121. In a case where silicon oxide is used as the interlayer insulating film 121, a thermal conductivity of silicon oxide is about 1.38 W/(m·K). On the other hand, for example, if the conductor layer 222 and the conductor layer 122′ are connected using the bump 230 made of tin, the heat of the second semiconductor chip 200 is about 50 times more easily conducted to the heat dissipation wiring 125.

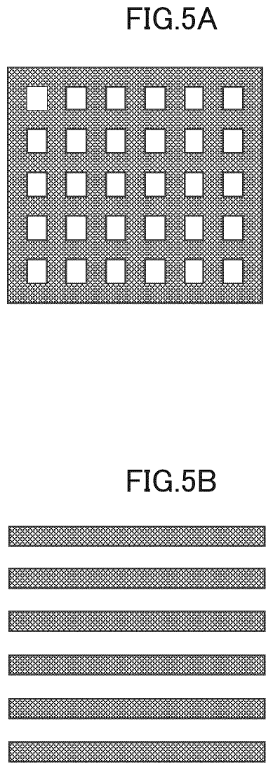

A shape of each conductor layer 122′ included in the heat dissipation wiring 125 in plan view may have a mesh-like wiring pattern as illustrated in FIG. 5A or may have a stripe-like wiring pattern as illustrated in FIG. 5B. By using such a wiring pattern, a wiring density can be increased, the thermal conductance is increased, and the heat dissipation efficiency is improved.

### Manufacturing Method of Radiation Detector

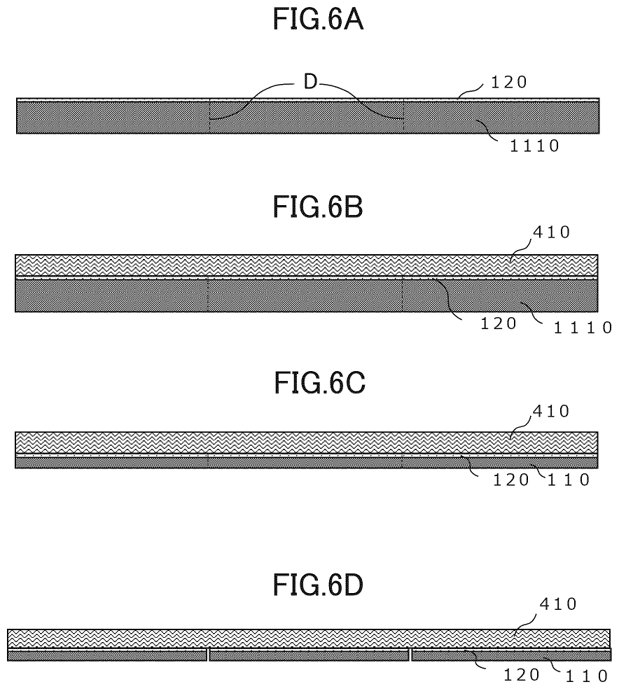

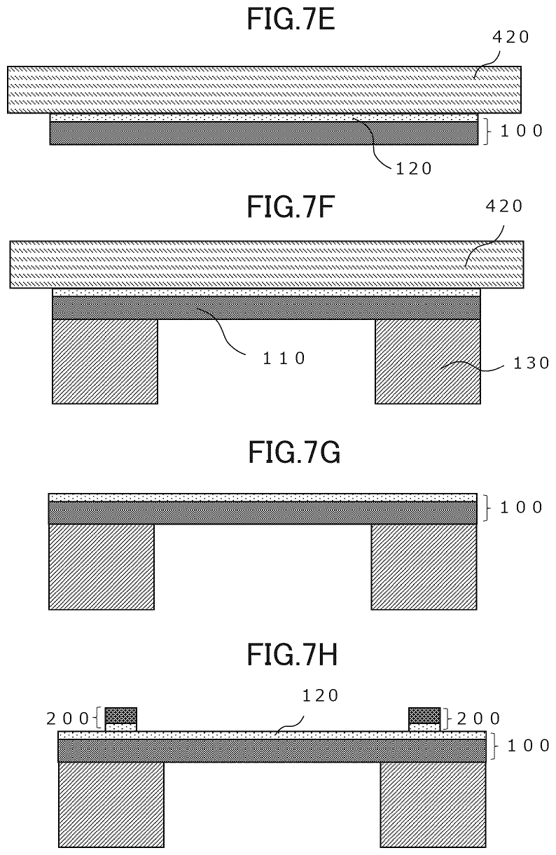

Next, a manufacturing method of the radiation detector 1 according to the present embodiment will be described. FIGS. 6A to 7H to be referred to below are schematic cross-sectional views for describing each stage of a manufacturing process.

First, in a manufacturing process (A) illustrated in FIG. 6A, a semiconductor element such as a MOS transistor is formed on a semiconductor wafer 1110, and the wiring layer 120 is formed on the semiconductor wafer 1110. The semiconductor wafer 1110 is a portion that becomes the semiconductor layer 110 through thinning processing later. A broken line D indicates a position where division in units of chips is to be performed in a subsequent manufacturing process.

In a manufacturing process (B) illustrated in FIG. 6B, a back grinding tape 410 adheres onto the wiring layer 120.

In a manufacturing process (C) illustrated in FIG. 6C, the semiconductor wafer 1110 is thinned to a predetermined thickness by back grinding to form the semiconductor layer 110.

In a manufacturing process (D) illustrated in FIG. 6D, a stacked body of the semiconductor layer 110 and the wiring layer 120 is diced so as to be divided in units of chips.

In a manufacturing process (E) illustrated in FIG. 7E, one chip obtained by division in units of chips, that is, the first semiconductor chip 100, is removed from the back grinding tape 410. Then, the chip fixing tape 420 is adhered and fixed to the wiring layer 120.

In a manufacturing process (F) illustrated in FIG. 7F, the support portion 130 is attached to the semiconductor layer 110 by an adhesive member.

In a manufacturing process (G) illustrated in FIG. 7G, the first semiconductor chip 100 is removed from the chip fixing tape 420.

In a manufacturing process (H) illustrated in FIG. 7H, the second semiconductor chip 200 prepared in advance is attached to the wiring layer 120 of the first semiconductor chip 100. In this way, the radiation detector 1 according to the present embodiment can be manufactured.

In the present embodiment, when the radiation detector 1 is viewed in plan (in a see-through manner) from a direction perpendicular to the principal surface of the first semiconductor chip 100, the end portion P1 of the support portion 130, which is positioned on the side closer to the detection region 10 among the end portions of the support portion 130, is disposed closer to the detection region 10 than the end portion P2 of the second semiconductor chip 200 is. Here, the end portion P2 is an end portion of the second semiconductor chip 200, which is positioned on the side closer to the outer edge of the first semiconductor chip 100 among the end portions of the second semiconductor chip 200.

In the present embodiment, at least a part of the support portion 130 is present between the detection region 10 and the second semiconductor chip 200 in plan view. Therefore, heat is efficiently transferred from both the detection region 10 and the second semiconductor chip 200 to the support portion 130. Since the heat from the detection region 10 and the second semiconductor chip 200 is efficiently dissipated via the support portion 130, noise such as the dark current is reduced, and the radiation detector with an improved radiation detection performance and a deterioration resistance can be provided.

The end portion of the support portion 130, which is positioned on the side closer to the outer edge of the first semiconductor chip 100 among the end portions of the support portion 130, that is, the end portion P3 positioned on the opposite side of the detection region 10, is disposed closer to the outer edge than the end portion P4 is, the end portion P4 being positioned on the side closer to the detection region 10 among the end portions of the second semiconductor chip 200. In plan view, the support portion 130 can be increased in size such that a part of the support portion 130 overlaps the second semiconductor chip 200, so that the mechanical strength of the radiation detector 1 is improved.

In addition, the second semiconductor chip 200 and the support portion 130 are disposed on different surfaces of the first semiconductor chip 100, the surfaces being positioned on opposite sides. That is, the support portion 130 is disposed on the surface of the first semiconductor chip 100, which is opposite to the surface on which the second semiconductor chip 200 is mounted, so that the mechanical strength of the peripheral region 20 of the thinned first semiconductor chip 100 is increased. Therefore, when pressure-bonding the second semiconductor chip 200 via the bump 230, it is possible to prevent the first semiconductor chip 100 from being damaged, by the first semiconductor chip 100 is supported by the support portion 130, and it is possible to manufacture the radiation detector with a high yield.

### Second Embodiment

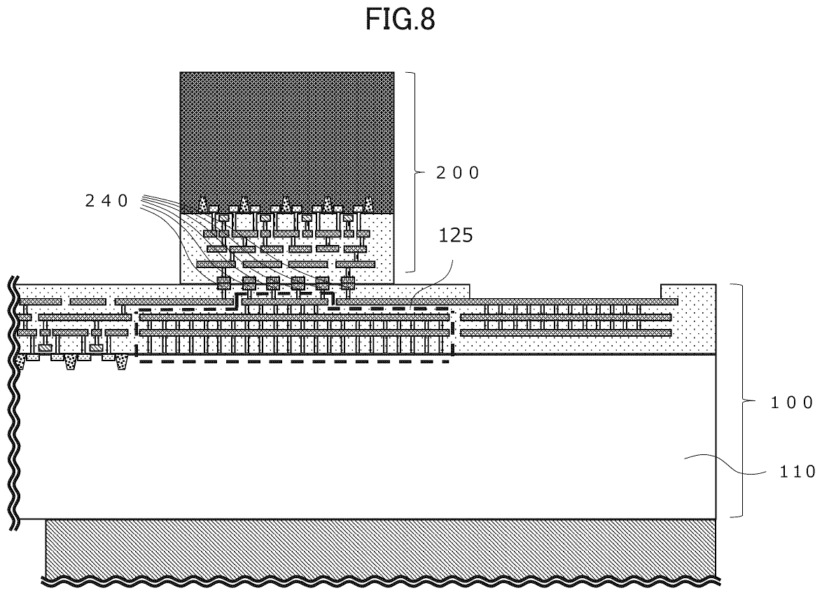

A radiation detector according to a second embodiment will be described with reference to FIGS. 1A and 8. A description of matters similar to the first embodiment will be simplified or omitted.

FIG. 8 is an enlarged cross-sectional view illustrating a portion where a second semiconductor chip 200 is mounted on a first semiconductor chip 100 in a peripheral region 20, that is, a portion F2 surrounded by a broken line in FIG. 1A in the present embodiment.

In the present embodiment, a wiring of the outermost layer of the first semiconductor chip 100 and a wiring of the outermost layer of the second semiconductor chip 200 are formed using copper (Cu) wirings. The copper wirings of the first semiconductor chip 100 and the second semiconductor chip 200 are brought into contact with each other and bonded to each other by applying a pressure, thereby forming a Cu—Cu hybrid bonding structure 240.

With the Cu—Cu hybrid bonding structure 240, since there is no restriction on an arrangement interval determined depending on a bump size unlike the bump connection structure described in the first embodiment, the arrangement interval of the copper wirings of a connection portion can be decreased. Therefore, the number of connection points between the second semiconductor chip 200 and a heat dissipation wiring 125 can be increased, so that heat of the second semiconductor chip 200 is easily conducted to the heat dissipation wiring 125.

### Third Embodiment

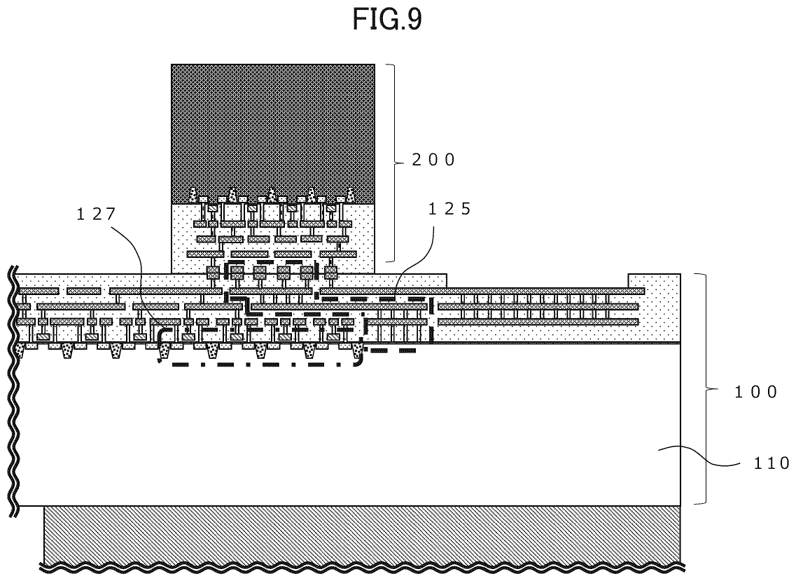

A radiation detector according to a third embodiment will be described with reference to FIGS. 1A and 9. A description of matters similar to the first embodiment will be simplified or omitted.

FIG. 9 is an enlarged cross-sectional view illustrating a portion where a second semiconductor chip 200 is mounted on a first semiconductor chip 100 in a peripheral region 20, that is, a portion F2 surrounded by a broken line in FIG. 1A in the present embodiment.

In the present embodiment, as illustrated in FIG. 9, in a semiconductor layer 110, a transistor 127 is disposed at a portion positioned below the second semiconductor chip 200. A heat dissipation wiring 125 is connected to the semiconductor layer 110 by using a via plug on a side closer to an outer edge of the first semiconductor chip 100 than the second semiconductor chip 200.

By adopting such a configuration, a control circuit, a signal processing circuit, and the like can be integrated in the first semiconductor chip 100, which is advantageous in terms of higher functionality and higher speed than in the first embodiment. Furthermore, since the signal processing circuit and the like of the first semiconductor chip 100 and the second semiconductor chip 200 can be laid out close to each other, a parasitic resistance and a parasitic capacitance of the wiring can be reduced. That is, since a signal delay can be reduced, it is also possible to achieve high-speed signal processing.

### Fourth Embodiment

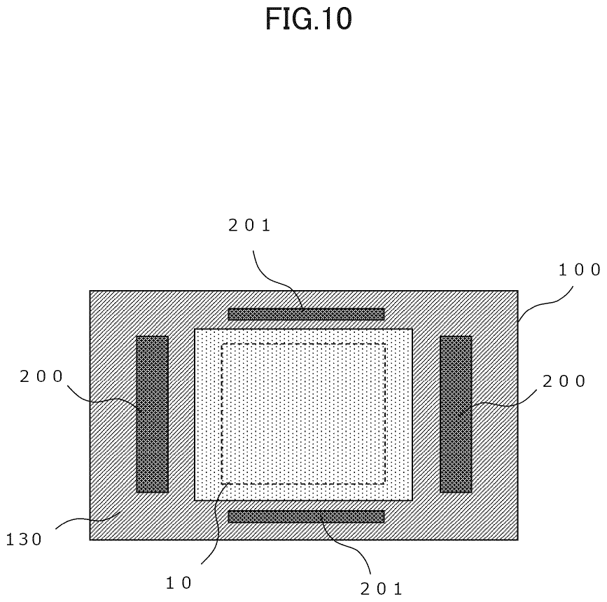

A radiation detector according to a fourth embodiment will be described with reference to FIGS. 1A, 1B, and 10. A description of matters similar to the first embodiment will be simplified or omitted.

The present embodiment is different from the first embodiment in a configuration illustrated in a plan view of FIG. 1B and an arrangement method of a second semiconductor chip. As illustrated in a plan view of FIG. 10, also in the present embodiment, second semiconductor chips 200 are disposed respectively along a set of sides facing each other with a detection region 10 interposed therebetween. In the present embodiment, other second semiconductor chips 201 are further disposed along sides intersecting the sides on which the second semiconductor chips 200 are disposed. In a case where a first semiconductor chip 100 is rectangular in plan view, it may be said that the second semiconductor chip is disposed along each of a long side and a short side of the first semiconductor chip 100.

According to the present embodiment, since a circuit having a new function can be added by disposing the plurality of second semiconductor chips, it is advantageous for enhancing functionality of the radiation detector. Alternatively, since a plurality of signal processing circuits can be mounted and perform parallel processing, a processing speed of the radiation detector can be increased.

### Fifth Embodiment

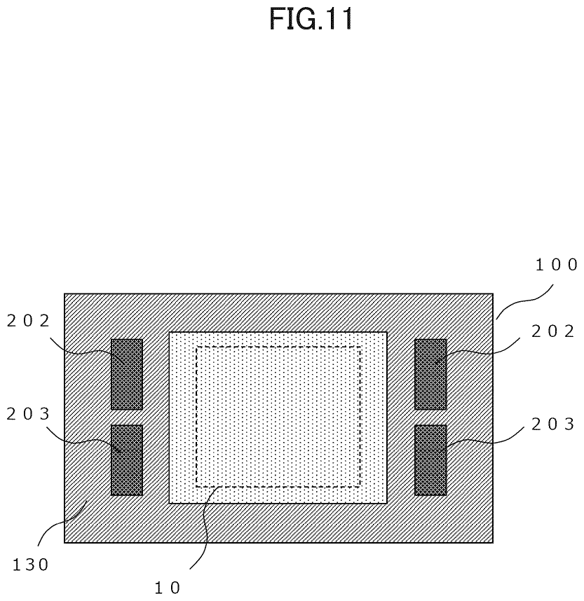

A radiation detector according to a fifth embodiment will be described with reference to FIGS. 1A, 1B, and 11. A description of matters similar to the first embodiment will be simplified or omitted.

The present embodiment is different from the first embodiment in a configuration illustrated in a plan view of FIG. 1B and an arrangement method of a second semiconductor chip. As illustrated in a plan view of FIG. 11, in the present embodiment, a second semiconductor chip 202 and a second semiconductor chip 203 are disposed along each side of a set of sides facing each other with a detection region 10 interposed therebetween.

According to the present embodiment, since the plurality of second semiconductor chips are disposed along one side of a first semiconductor chip 100, a plurality of signal processing circuits can be mounted. For example, since parallel processing can be performed using the plurality of second semiconductor chips, it is possible to increase a processing speed of the radiation detector.

### Sixth Embodiment

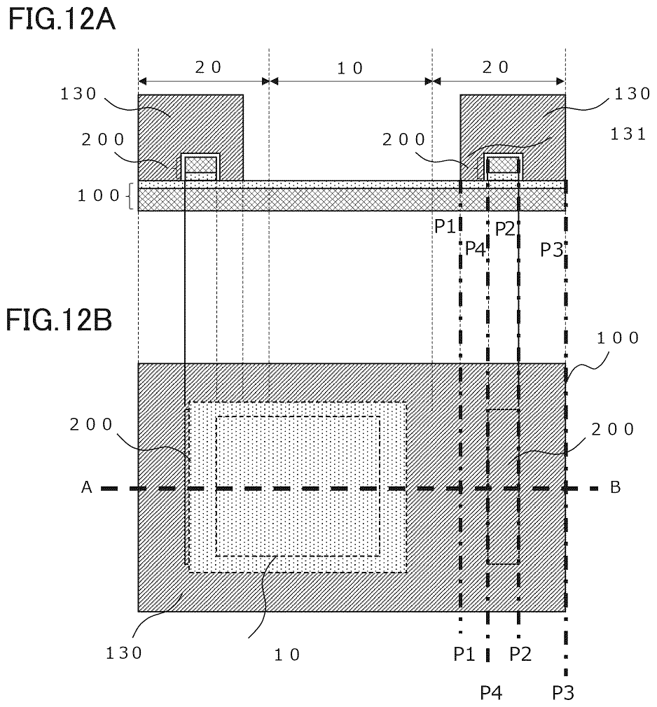

A radiation detector according to a sixth embodiment will be described with reference to FIGS. 12A to 14H. In the following description, a description of matters similar to the first embodiment will be simplified or omitted.

### Basic Configuration of Radiation Detector

FIG. 12A is a cross-sectional view of the radiation detector according to the present embodiment, and FIG. 12B is a plan view of the radiation detector when viewed in plan from above. FIG. 12A corresponds to a cross-sectional view taken along line A-B of FIG. 12B.

The present embodiment is different from the first embodiment in a position where a support portion 130 is disposed. In the present embodiment, as illustrated in FIG. 12A, a second semiconductor chip 200 and the support portion 130 are disposed on the same surface of a first semiconductor chip 100 in a peripheral region 20. The support portion 130 includes a recess 131 and is disposed such that the recess 131 is fitted to the second semiconductor chip 200.

A positional relationship between the second semiconductor chip 200 and the support portion 130 will be described in more detail. In the cross-sectional view of FIG. 12A and the plan view of FIG. 12B, lines P1 to P4 with alternating long and short dashes are illustrated in order to facilitate understanding of a correspondence relationship between positions in both drawings. P1 indicates a position of an end portion of the support portion 130, the end portion being on a side closer to a detection region 10 (detection region side) among end portions of the support portion 130. P2 indicates a position of an end portion of the second semiconductor chip 200, the end portion being on a side farther from the detection region 10 (in other words, an end portion closer to an outer edge of the first semiconductor chip 100). P3 indicates a position of an end portion of the support portion 130 on an outer edge side (in other words, a side of the first semiconductor chip 100 that is farther from the detection region 10). P4 indicates a position of an end portion of the second semiconductor chip 200, the end portion being on a side closer to the detection region 10 (in other words, an end portion farther from the outer edge of the first semiconductor chip 100).

As in the first embodiment, the end portion (P1) of the support portion 130 on the side closer to the detection region 10 is disposed closer to the detection region 10 than the end portion (P2) of the second semiconductor chip 200 on the side closer to the outer edge. In addition, the end portion (P3) of the support portion 130 on the side closer to the outer edge is disposed closer to the outer edge of the first semiconductor chip 100 than the end portion (P4) of the second semiconductor chip 200 on the side closer to the detection region 10.

With a configuration in which at least a part of the support portion 130 and the second semiconductor chip 200 overlap each other in plan view, heat of the second semiconductor chip 200 can be efficiently dissipated to the support portion 130. Since the heat of the second semiconductor chip 200 is efficiently dissipated via the support portion 130, the heat conducted from the second semiconductor chip 200 to the detection region 10 of the first semiconductor chip 100 is reduced, and noise such as the dark current generated in the detection region 10 is reduced.

### Manufacturing Method of Radiation Detector

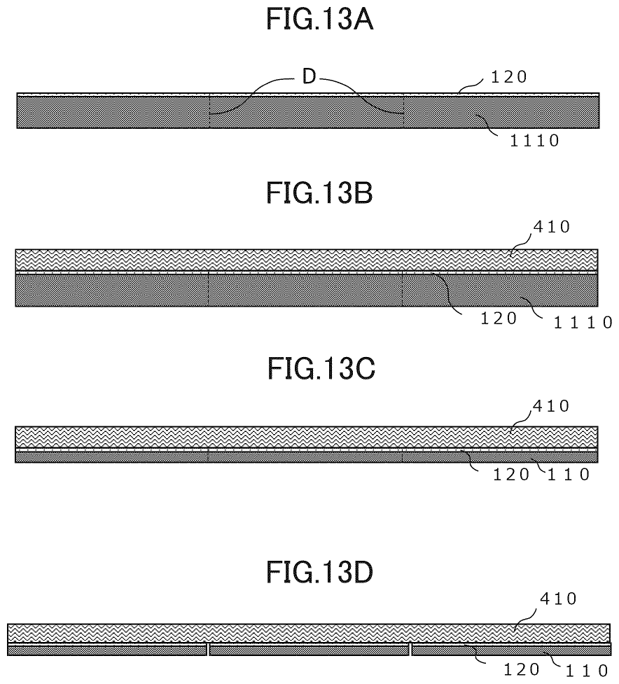

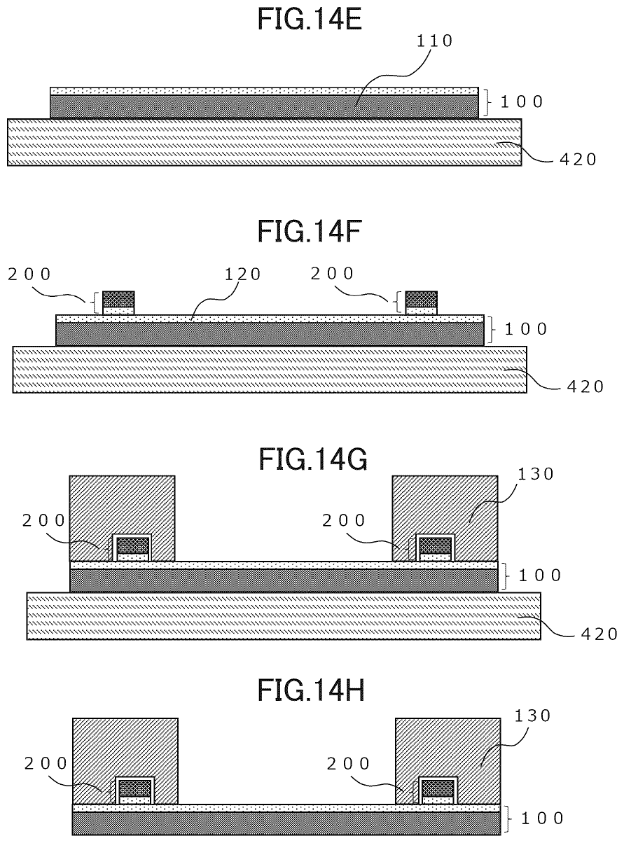

Next, a manufacturing method of the radiation detector according to the present embodiment will be described. FIGS. 13A to 14H to be referred to below are schematic cross-sectional views for describing each stage of a manufacturing process. Since a manufacturing process (A) illustrated in FIG. 13A to a manufacturing process (D) illustrated in FIG. 13D are similar to those of the first embodiment described with reference to FIGS. 6A to 6D, a description thereof is omitted.

In a manufacturing process (E) illustrated in FIG. 14E, one chip obtained by division in units of chips, that is, the first semiconductor chip 100, is removed from a back grinding tape 410. Then, the first semiconductor chip 100 adheres to a chip fixing tape 420 and is fixed to a semiconductor layer 110.

In a manufacturing process (F) illustrated in FIG. 14F, the second semiconductor chip 200 prepared in advance is attached to a wiring layer 120 of the first semiconductor chip 100.

In a manufacturing process (G) illustrated in FIG. 14G, the recess of the support portion 130 is positioned so as to be fitted to the second semiconductor chip 200, and is attached by adhering using an adhesive member. In order to improve heat dissipation efficiency, it is preferable to use an adhesive member having a high thermal conductivity.

In a manufacturing process (H) illustrated in FIG. 14H, the first semiconductor chip 100 is removed from the chip fixing tape 420. In this way, the radiation detector according to the present embodiment can be manufactured.

Also in the present embodiment, when the radiation detector is viewed in plan (in a see-through manner) from a direction perpendicular to the principal surface of the first semiconductor chip 100, the end portion P1 of the support portion 130 positioned on the side closer to the detection region 10 among the end portions of the support portion 130 is disposed closer to the detection region 10 than the end portion P2 of the second semiconductor chip 200 is. Here, the end portion P2 is an end portion of the second semiconductor chip 200, which is positioned on the side closer to the outer edge of the first semiconductor chip 100 among the end portions of the second semiconductor chip 200.

Also in the present embodiment, at least a part of the support portion 130 is present between the detection region 10 and the second semiconductor chip 200 in plan view. Therefore, heat is efficiently transferred from both the detection region 10 and the second semiconductor chip 200 to the support portion 130. Since the heat from the detection region 10 and the second semiconductor chip 200 is efficiently dissipated via the support portion 130, noise such as a dark current is reduced, and the radiation detector with an improved radiation detection performance and a deterioration resistance can be provided.

Also in the present embodiment, the end portion of the support portion 130, which is positioned on the side closer to the outer edge of the first semiconductor chip 100 among the end portions of the support portion 130, that is, the end portion P3 positioned on the opposite side of the detection region 10, is disposed on the side closer to the outer edge of the first semiconductor chip 100 than the end portion P4 is, the end portion P4 being positioned on the side closer to the detection region 10 among the end portions of the second semiconductor chip 200. In plan view, the support portion 130 overlaps the second semiconductor chip 200. Therefore, a size of the support portion 130 can be increased, so that a mechanical strength of the radiation detector is improved.

According to the present embodiment, the second semiconductor chip 200 and the support portion 130 are disposed on the same surface of the first semiconductor chip 100. The support portion 130 includes the recess 131 and is disposed so as to be fitted to the second semiconductor chip 200. That is, the second semiconductor chip 200 is covered with the support portion 130. Therefore, when radiation is applied to the detection region 10, it is possible to block the scattered radiation from reaching the second semiconductor chip 200 by the support portion 130, so that it is possible to suppress a malfunction and a failure of the second semiconductor chip 200.

### Seventh Embodiment

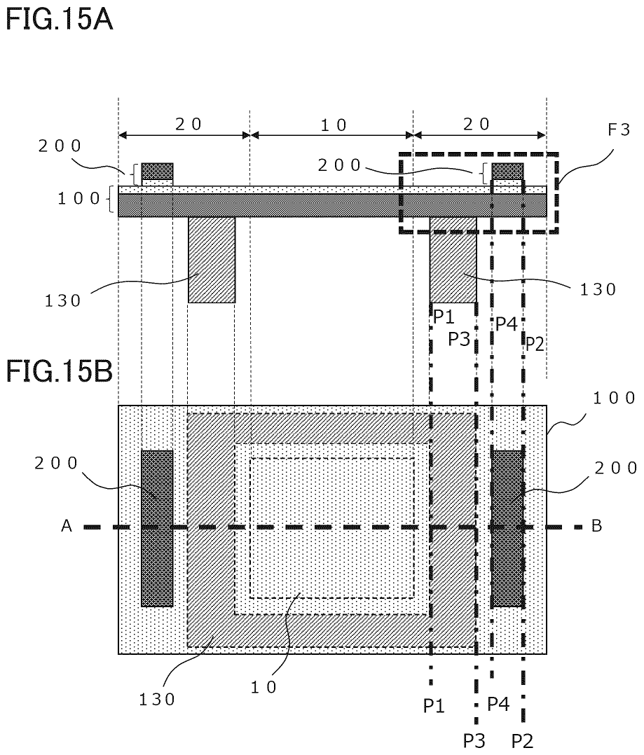

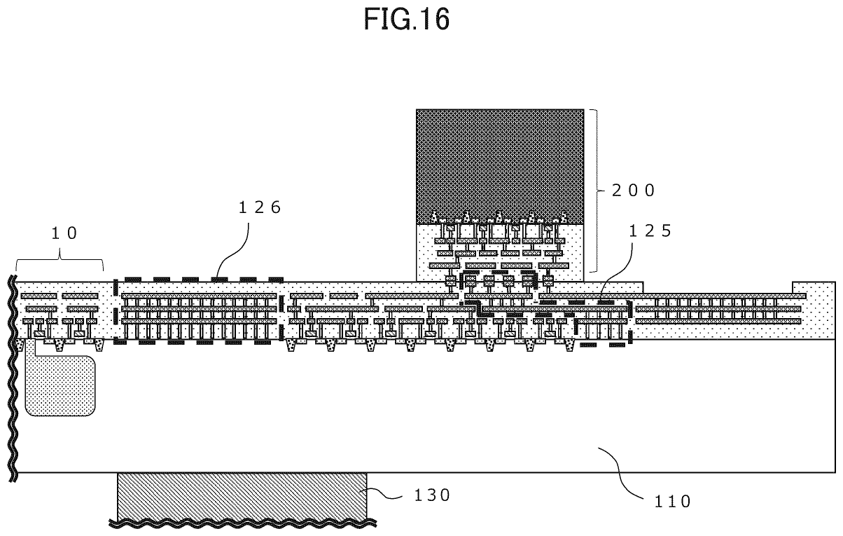

A radiation detector according to a seventh embodiment will be described with reference to FIGS. 15A, 15B, and 16. In the following description, a description of matters similar to the first embodiment will be simplified or omitted. Basic Configuration of Radiation Detector

FIG. 15A is a cross-sectional view of the radiation detector according to the present embodiment, and FIG. 15B is a plan view of the radiation detector when viewed in plan from above. FIG. 15A corresponds to a cross-sectional view taken along line A-B of FIG. 15B.

The present embodiment is different from the first embodiment in a position where a support portion 130 is disposed. In the present embodiment, as illustrated in FIG. 15A, a second semiconductor chip 200 and the support portion 130 are respectively disposed on opposite surfaces of a first semiconductor chip 100 as in the first embodiment. However, a positional relationship between the second semiconductor chip 200 and the support portion 130 in plan view is different from that of the first embodiment.

In the cross-sectional view of FIG. 15A and the plan view of FIG. 15B, lines P1 to P4 with alternating long and short dashes are illustrated in order to facilitate understanding of a correspondence relationship between positions in both drawings. P1 indicates a position of an end portion of the support portion 130, the end portion being on a side closer to a detection region 10 (detection region side) among end portions of the support portion 130. P2 indicates a position of an end portion of the second semiconductor chip 200, the end portion being on a side farther from the detection region 10 (in other words, an end portion closer to an outer edge of the first semiconductor chip 100). P3 indicates a position of an end portion of the support portion 130 on an outer edge side (in other words, a side of the first semiconductor chip 100 that is farther from the detection region 10). P4 indicates a position of an end portion of the second semiconductor chip 200, the end portion being on a side closer to the detection region 10 (in other words, an end portion farther from the outer edge of the first semiconductor chip 100).

The end portion (P1) of the support portion 130 on the side closer to the detection region 10 is disposed closer to the detection region 10 than the end portion (P2) of the second semiconductor chip 200 on the side closer to the outer edge, as in the first embodiment. On the other hand, unlike the first embodiment, the end portion (P3) of the support portion 130 on the outer edge side is disposed closer to the detection region 10 than the end portion (P4) of the second semiconductor chip 200 is, the end portion (P4) being on the side closer to the detection region 10. With such a positional relationship, the support portion 130 is disposed between the detection region 10 and the second semiconductor chip 200 in plan view.

### Manufacturing Method of Radiation Detector

A manufacturing method of the radiation detector according to the present embodiment can be similar to the manufacturing method of the radiation detector according to the first embodiment except that the second semiconductor chip 200 and the support portion 130 are disposed at different positions in plan view, and thus a description thereof is omitted.

### Mounting of Second Semiconductor Chip

A structure of a portion where the second semiconductor chip 200 is mounted on the first semiconductor chip 100 in the radiation detector will be described. FIG. 16 is an enlarged cross-sectional view illustrating a portion where the second semiconductor chip 200 is mounted on the first semiconductor chip 100 in a peripheral region 20, that is, a portion F3 surrounded by a broken line in FIG. 15A.

In the first semiconductor chip 100, a heat dissipation wiring 125 is disposed at a position overlapping the second semiconductor chip 200 in plan view, and heat of the second semiconductor chip 200 can be efficiently dissipated via the heat dissipation wiring 125. As illustrated, another heat dissipation wiring 126 may be disposed at a position overlapping the support portion 130 in plan view. By disposing the heat dissipation wiring 126 in the vicinity of the detection region 10, heat of the detection region 10 can be efficiently dissipated. By connecting the heat dissipation wiring 126 to the semiconductor layer 110, heat dissipation efficiency can be further improved.

In the cross-sectional view of FIG. 15A and the plan view of FIG. 15B, lines P1 to P4 with alternating long and short dashes are illustrated in order to facilitate understanding of a correspondence relationship between positions in both drawings. P1 indicates a position of an end portion of the support portion 130, the end portion being on a side closer to a detection region 10 (detection region side) among end portions of the support portion 130. P2 indicates a position of an end portion of the second semiconductor chip 200, the end portion being on a side farther from the detection region 10 (in other words, an end portion closer to an outer edge of the first semiconductor chip 100). P3 indicates a position of an end portion of the support portion 130 on an outer edge side (in other words, a side of the first semiconductor chip 100 that is farther from the detection region 10). P4 indicates a position of an end portion of the second semiconductor chip 200, the end portion being on a side closer to the detection region 10 (in other words, an end portion farther from the outer edge of the first semiconductor chip 100).

As in the first embodiment, the end portion (P1) of the support portion 130 on the side closer to the detection region 10 is disposed closer to the detection region 10 than the end portion (P2) of the second semiconductor chip 200 on the side closer to the outer edge. That is, at least a part of the support portion 130 is positioned between the detection region 10 and the second semiconductor chip 200 in plan view. Therefore, heat from both the detection region 10 and the second semiconductor chip 200 is efficiently dissipated via the support portion 130. By cooling the support portion 130, it is possible to provide the radiation detector in which the heat dissipation efficiency is further enhanced, noise is suppressed, and detection performance is improved.

In the present embodiment, the end portion (P3) of the support portion 130 on the outer edge side is disposed closer to the detection region 10 than the end portion P4 of the second semiconductor chip 200 is, the end portion P4 being on the side closer to the detection region 10. That is, the support portion 130 is disposed between the detection region 10 and the second semiconductor chip 200 in plan view. Since an amount of heat generation of the second semiconductor chip 200 is increased as functionality and speed are enhanced, it is desirable to position the second semiconductor chip 200 away from the detection region 10 in order to make it difficult for the heat to be transferred to the detection region 10 of the first semiconductor chip 100. In the present embodiment, as compared with the first embodiment, the second semiconductor chip 200 can be positioned farther away from the detection region 10 with the support portion 130 interposed therebetween. Therefore, even if the second semiconductor chip 200 is enhanced in functionality and speed, the detection region 10 can be hardly affected by the heat generation of the second semiconductor chip 200.

In addition, the second semiconductor chip 200 and the support portion 130 are disposed on different surfaces of the first semiconductor chip 100, the surfaces being positioned on opposite sides. That is, the support portion 130 is disposed on a surface of the first semiconductor chip 100, the surface being opposite to a surface on which the second semiconductor chip 200 is stacked.

Therefore, when manufacturing the radiation detector, the second semiconductor chip 200 and the support portion 130 do not come into contact with each other in a process of disposing the second semiconductor chip 200 and the support portion 130 on the first semiconductor chip 100. The support portion 130 can be disposed using a simple alignment mechanism, thereby facilitating manufacturing.

### Eighth Embodiment

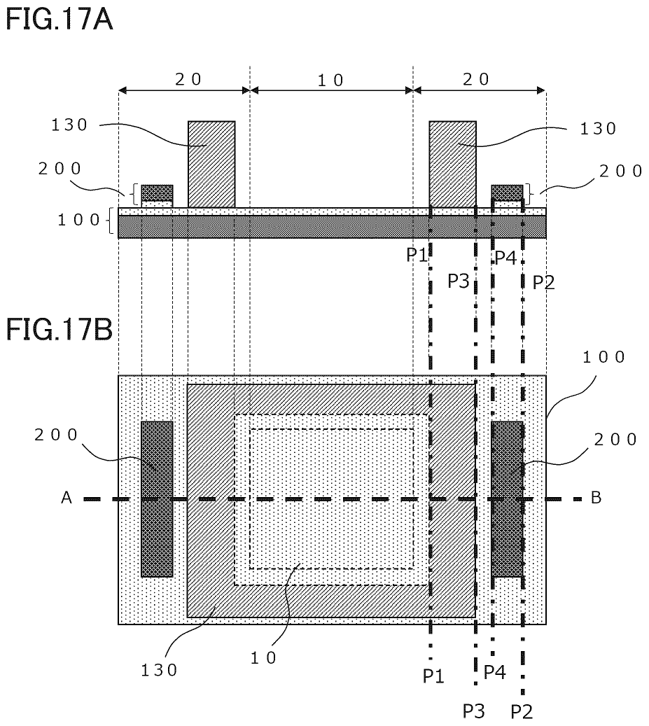

A radiation detector according to an eighth embodiment will be described with reference to FIGS. 17A and 17B. A description of matters similar to the first embodiment will be simplified or omitted.

### Basic Configuration of Radiation Detector

FIG. 17A is a cross-sectional view of the radiation detector according to the eighth embodiment, and FIG. 17B is a plan view of the radiation detector when viewed in plan from above. FIG. 17A corresponds to a cross-sectional view taken along line A-B of FIG. 17B.

The present embodiment is a modified example of the seventh embodiment and is different from the seventh embodiment in a position where a support portion 130 is disposed. In the present embodiment, as illustrated in FIG. 17B, the support portion 130 is disposed between a detection region 10 and a second semiconductor chip 200 in plan view as in the seventh embodiment. However, in the present embodiment, as illustrated in FIG. 17A, the second semiconductor chip 200 and the support portion 130 are disposed on the same surface of a first semiconductor chip 100 in a peripheral region 20, unlike the seventh embodiment.

In the cross-sectional view of FIG. 17A and the plan view of FIG. 17B, lines P1 to P4 with alternating long and short dashes are illustrated in order to facilitate understanding of a correspondence relationship between positions in both drawings. P1 indicates a position of an end portion of the support portion 130, the end portion being on a side closer to a detection region 10 (detection region side) among end portions of the support portion 130. P2 indicates a position of an end portion of the second semiconductor chip 200, the end portion being on a side farther from the detection region 10 (in other words, an end portion closer to an outer edge of the first semiconductor chip 100). P3 indicates a position of an end portion of the support portion 130 on an outer edge side (in other words, a side of the first semiconductor chip 100 that is farther from the detection region 10). P4 indicates a position of an end portion of the second semiconductor chip 200, the end portion being on a side closer to the detection region 10 (in other words, an end portion farther from the outer edge of the first semiconductor chip 100).

The end portion (P1) of the support portion 130 on the side closer to the detection region 10 is disposed closer to the detection region 10 than the end portion (P2) of the second semiconductor chip 200 on the side closer to the outer edge, as in the first embodiment. On the other hand, as in the seventh embodiment, the end portion (P3) of the support portion 130 on the outer edge side is disposed closer to the detection region 10 than the end portion (P4) of the second semiconductor chip 200 is, the end portion (P4) being on the side closer to the detection region 10. With such a positional relationship, the support portion 130 is disposed between the detection region 10 and the second semiconductor chip 200 in plan view.

### Manufacturing Method of Radiation Detector

As in the sixth embodiment, the second semiconductor chip 200 and the support portion 130 are disposed on the same surface of the first semiconductor chip 100, and the same manufacturing method as that of the radiation detector according to the sixth embodiment can be applied as a manufacturing method of the radiation detector according to the present embodiment.

In the present embodiment, as in the seventh embodiment, the support portion 130 is disposed between the detection region 10 and the second semiconductor chip 200. Therefore, heat from both the detection region 10 and the second semiconductor chip 200 is efficiently dissipated via the support portion 130. By cooling the support portion 130, it is possible to provide the radiation detector in which the heat dissipation efficiency is further enhanced, noise is suppressed, and detection performance is improved.

Since an amount of heat generation of the second semiconductor chip 200 is greatly increased as functionality and speed are enhanced, it is desirable to position the second semiconductor chip 200 away from the detection region 10 in order to make it difficult for the heat to be transferred to the detection region 10 of the first semiconductor chip 100. In the present embodiment, as compared with the first embodiment, the second semiconductor chip 200 can be positioned farther from the detection region 10 with the support portion 130 interposed. Therefore, even if the second semiconductor chip 200 is enhanced in functionality and speed, the detection region 10 can be hardly affected by the heat generation of the second semiconductor chip 200.

In the present embodiment, unlike the seventh embodiment, the second semiconductor chip 200 and the support portion 130 are disposed on the same surface of the first semiconductor chip 100, and like the seventh embodiment, the support portion 130 is disposed between the detection region 10 and the second semiconductor chip 200.

In such a structure, when radiation is applied to the detection region 10, it is possible to block the scattered radiation from reaching the second semiconductor chip 200 by the support portion 130, so that it is possible to suppress a malfunction and a failure of the second semiconductor chip 200. Unlike the sixth embodiment, it is not necessary to form a recess in the support portion 130, so that a manufacturing cost of the support portion 130 can be reduced.

### Ninth Embodiment

A radiation detector according to a ninth embodiment will be described. In the following description, a description of matters similar to the first embodiment will be simplified or omitted.

### Basic Configuration of Radiation Detector

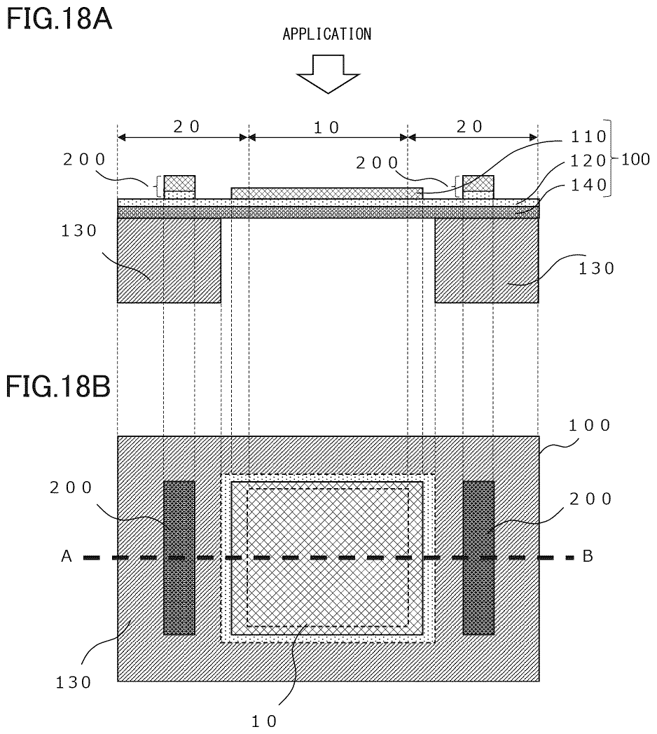

FIG. 18A is a cross-sectional view of the radiation detector according to the present embodiment, and FIG. 18B is a plan view of the radiation detector when viewed in plan from above. FIG. 18A corresponds to a cross-sectional view taken along line A-B of FIG. 18B.

The present embodiment is different from the first embodiment in a configuration of a first semiconductor chip 100. In the first semiconductor chip 100 in the present embodiment, in addition to a semiconductor layer 110 and a wiring layer 120, a support substrate 140 is bonded to a surface on which the wiring layer 120 is formed.

Since the first semiconductor chip 100 includes the support substrate 140, a mechanical strength of the first semiconductor chip 100 can be secured even if a thickness of the semiconductor layer 110 is further reduced. A material of the support substrate 140 may be any one of a semiconductor, an insulator, and a conductor as long as the material has sufficient stiffness to support the semiconductor layer 110. However, in order to reduce a stress (for example, thermal stress) acting between the semiconductor layer 110 and the support substrate 140, the material of the support substrate 140 is preferably the same type of semiconductor material as that of the semiconductor layer 110. That is, if the semiconductor layer 110 is a silicon layer, the support substrate 140 is preferably made of silicon, and if the semiconductor layer 110 is a germanium layer, the support substrate 140 is preferably made of germanium.

In the present embodiment, a thickness of the first semiconductor chip 100 substantially corresponds to the sum of thicknesses of the semiconductor layer 110, the wiring layer 120, and the support substrate 140, and is, for example, 1 μm or more and 1000 μm or less. The thickness is typically more than 10 μm and less than 100 μm, and preferably 25 μm or more and 75μm or less. The thickness of the semiconductor layer 110 is 0.5 μm or more and 200 μm or less, typically more than 5 μm and less than 50 μm, and preferably 15 μm or more and 25 μm or less.

In the present embodiment, as in the first embodiment, a second semiconductor chip 200 and a support portion 130 are disposed on different surfaces of the first semiconductor chip 100, the surfaces being positioned on opposite sides. That is, the support portion 130 is disposed on the surface of the first semiconductor chip 100, the surface being opposite to the surface on which the second semiconductor chip 200 is mounted. In addition, a positional relationship among the first semiconductor chip 100, the second semiconductor chip 200, and the support portion 130 in plan view is also the same as that in the first embodiment, and thus a description thereof is omitted.

### Manufacturing Method of Radiation Detector

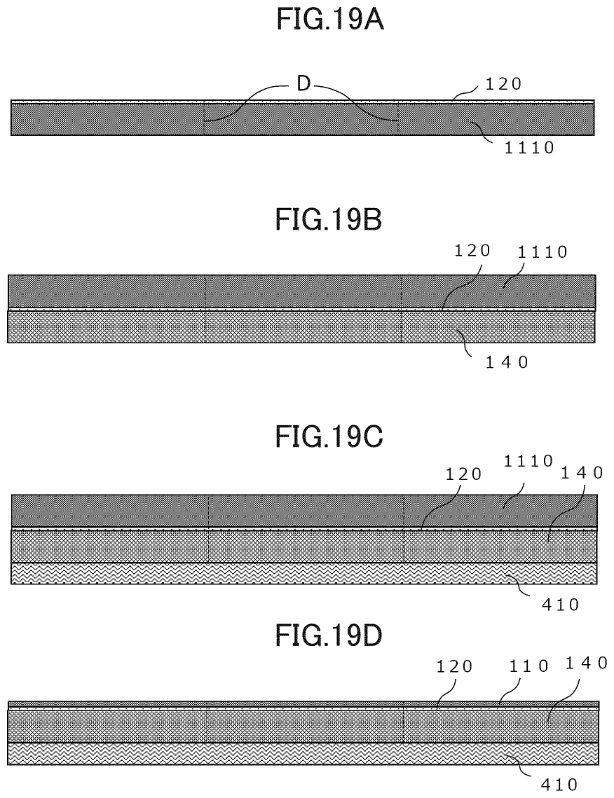

Next, a manufacturing method of the radiation detector according to the present embodiment will be described. FIGS. 19A to 22L referred to below are schematic cross-sectional views for describing each stage of a manufacturing process.

First, in a manufacturing process (A) illustrated in FIG. 19A, a semiconductor element such as a MOS transistor is formed on a semiconductor wafer 1110, and the wiring layer 120 is formed on the semiconductor wafer 1110. The semiconductor wafer 1110 is a portion that becomes the semiconductor layer 110 through thinning processing later. A broken line D indicates a position where division in units of chips is to be performed in a subsequent manufacturing process.

In a manufacturing process (B) illustrated in FIG. 19B, the support substrate 140 is bonded to a surface of the semiconductor wafer 1110 on which the wiring layer 120 is formed.

In a manufacturing process (C) illustrated in FIG. 19C, a back grinding tape 410 adheres to the support substrate 140.

In a manufacturing process (D) illustrated in FIG. 19D, the semiconductor wafer 1110 is thinned to a predetermined thickness by back grinding to form the semiconductor layer 110.

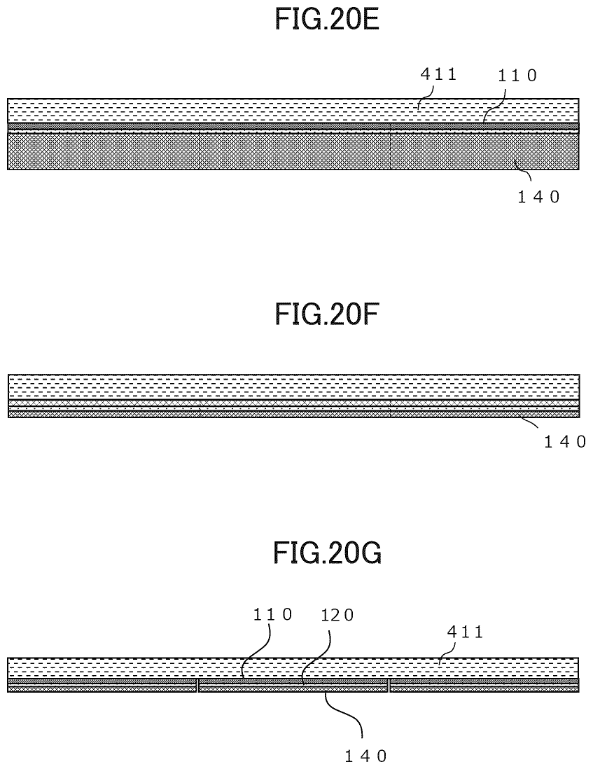

In a manufacturing process (E) illustrated in FIG. 20E, the back grinding tape 410 is removed, and a back grinding tape 411 adheres to the semiconductor layer 110.

In a manufacturing process (F) illustrated in FIG. 20F, the support substrate 140 is thinned to a predetermined thickness by back grinding.

In a manufacturing process (G) illustrated in FIG. 20G, a stacked body of the support substrate 140, the wiring layer 120, and the semiconductor layer 110 is diced so as to be divided in units of chips.

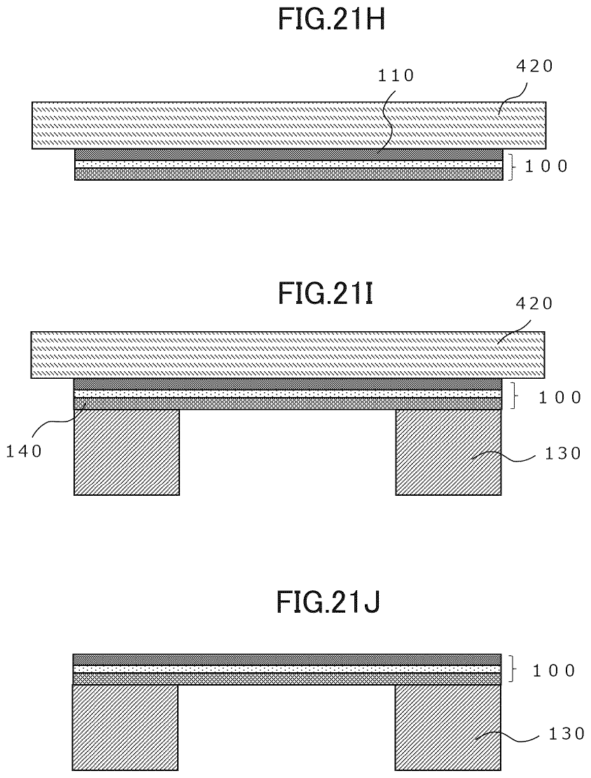

In a manufacturing process (H) illustrated in FIG. 21H, one chip obtained by division in units of chips, that is, the first semiconductor chip 100, is removed from the back grinding tape 411, and a chip fixing tape 420 is adhered and fixed to the surface of the semiconductor layer 110.

In a manufacturing process (I) illustrated in FIG. 21I, the support portion 130 is attached to the support substrate 140 by an adhesive member.

In a manufacturing process (J) illustrated in FIG. 21J, the chip fixing tape 420 is removed from the first semiconductor chip 100.

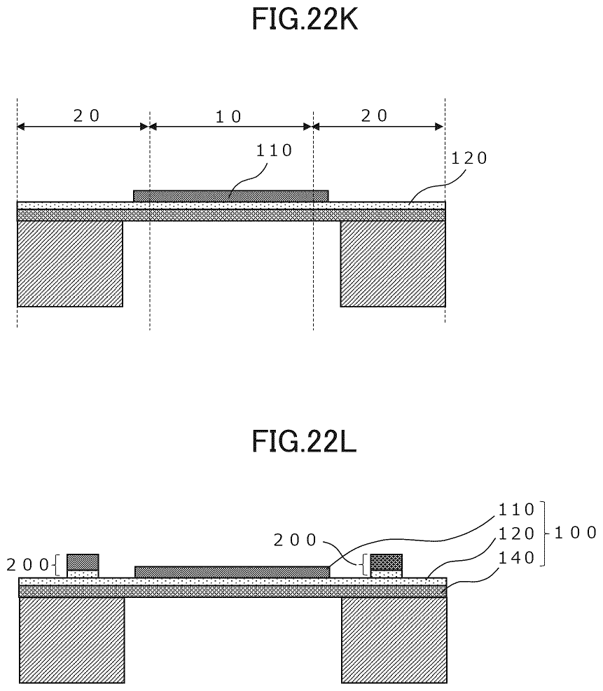

In a manufacturing process (K) illustrated in FIG. 22K, the semiconductor layer 110 in the detection region 10 is left, and at least a part of the semiconductor layer 110 in the peripheral region 20 is removed by etching or the like to expose a surface of the wiring layer 120.

In a manufacturing process (L) illustrated in FIG. 22L, the second semiconductor chip 200 prepared in advance is attached onto the exposed wiring layer 120 of the first semiconductor chip 100. In this way, the radiation detector according to the present embodiment can be manufactured.

As described above, in the present embodiment, the first semiconductor chip 100 includes the support substrate 140 bonded to the surface of the wiring layer 120 is formed, in addition to the semiconductor layer 110 and the wiring layer 120. With such a configuration, radiation is not injected to the semiconductor layer 110 after passing through the wiring layer 120, but is directly applied to the semiconductor layer. Since the radiation is not scattered by the wiring layer 120 before being injected to the semiconductor layer 110, a resolution of an obtained detection image is improved.

In addition, since the support substrate 140 is provided, the semiconductor layer 110 can be further thinned while securing the mechanical strength of the first semiconductor chip 100. Therefore, the resolution can be further improved.

In addition, the semiconductor layer 110 in the peripheral region 20 is removed to expose the wiring layer 120, and the second semiconductor chip 200 is stacked thereon. Therefore, electrical connection between the first semiconductor chip 100 and the second semiconductor chip 200 can be easily achieved using a bump connection structure or a Cu—Cu hybrid bonding structure.

A configuration in which a stacked body in which the support substrate 140, the wiring layer 120, and the semiconductor layer 110 are arranged in this order is formed, and radiation is directly applied to the semiconductor layer 110 as in the present embodiment can be implemented not only as a modified example of the first embodiment but also as a modified example of another embodiment.

### Tenth Embodiment

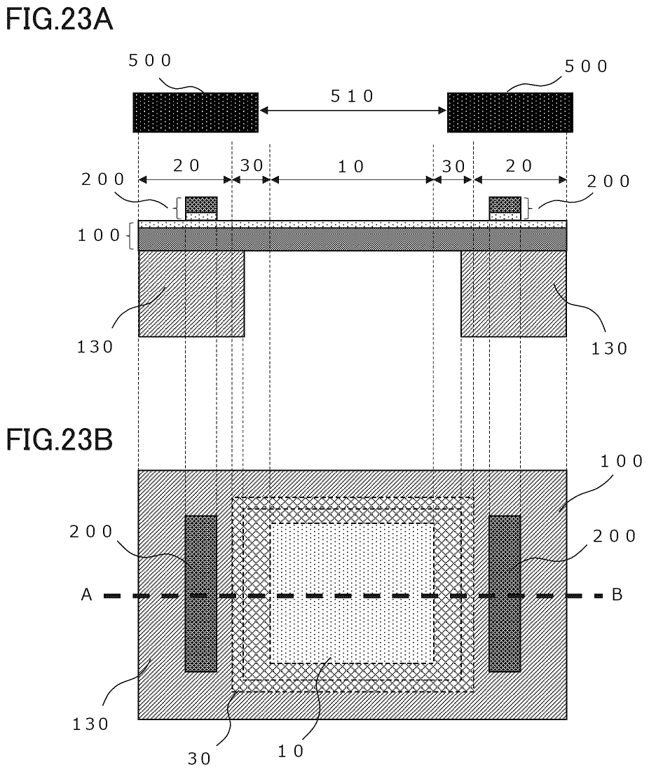

A radiation detector according to a tenth embodiment will be described with reference to FIGS. 23A and 23B. A description of matters similar to the first embodiment will be simplified or omitted.

FIG. 23A is a cross-sectional view of the radiation detector according to the present embodiment, and FIG. 23B is a plan view of the radiation detector when viewed in plan from above. FIG. 23A corresponds to a cross-sectional view taken along line A-B of FIG. 23B.

In the present embodiment, unlike the first embodiment, a first semiconductor chip 100 includes a buffer region 30 between a detection region 10 for detecting radiation and a peripheral region 20. In the plan view of FIG. 23B, a position of the buffer region 30 is highlighted with a shaded texture.

As illustrated in FIG. 23A, in the radiation detector according to the present embodiment, a blocking member 500 is installed on a side to which radiation is applied. The blocking member 500 is made of a material capable of blocking radiation and has an opening portion 510 at a position corresponding to the detection region 10. The blocking member 500 is disposed such that radiation is applied to the detection region 10 but does not reach the peripheral region 20.

Since the blocking member 500 is provided, generation of charges due to radiation is suppressed in the peripheral region 20, and thus a malfunction and a failure of a circuit disposed in the peripheral region 20 are prevented.

The blocking member 500 is disposed such that an end portion of the opening portion 510 is positioned above the buffer region 30. The buffer region 30 is a region disposed in consideration of variations in alignment of the blocking member 500, spread of radiation extending around a circuit of the peripheral region 20 from the opening portion 510, and the like. Considering scattering of radiation in a semiconductor substrate, it is preferable to dispose the buffer region 30 such that a distance between the detection region 10 and the peripheral region 20 is 200 μm or more.

In the buffer region 30, a semiconductor element such as a transistor forming a control circuit, a signal processing circuit, or the like is not disposed, and a conductor layer such as a power supply wiring, a signal wiring, or a dummy wiring is disposed. The conductor layer is applied with a potential so as not to be electrically floating. When a potential is applied, the charges generated by radiation application are discharged from the conductor layer, and breakdown of an insulating layer due to charge-up can be prevented.

In plan view, at least a part of the support portion 130 is disposed in the buffer region 30. By disposing at least a part of the support portion 130 in the buffer region 30, an area for supporting the first semiconductor chip 100 can be increased, so that a mechanical strength of the radiation detector can be increased. In addition, it is preferable that the second semiconductor chip 200 is not disposed in the buffer region 30 in plan view in order to prevent a malfunction and a failure.

A configuration in which the buffer region 30 and/or the blocking member 500 are provided as in the present embodiment can be implemented not only as a modified example of the first embodiment but also as a modified example of another embodiment.

### Eleventh Embodiment

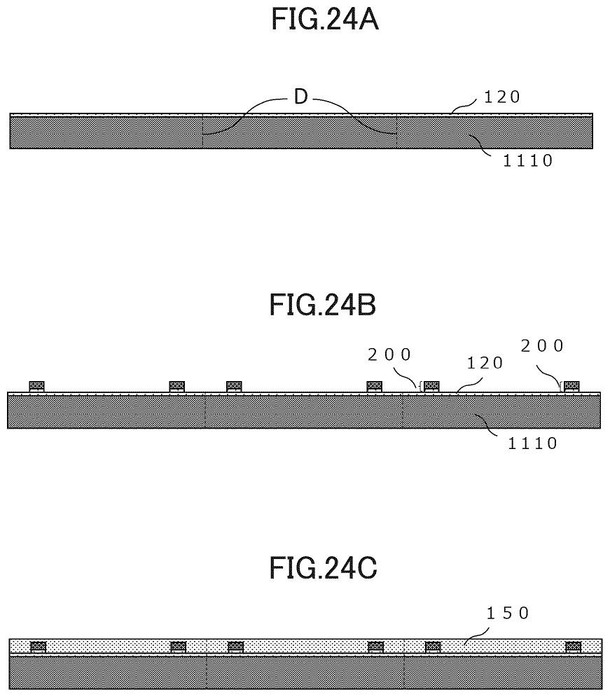

A radiation detector according to an eleventh embodiment will be described with reference to FIGS. 24A to 26I. In the following description, a detailed description of portions similar to those of the first embodiment is omitted.

### Basic Configuration of Radiation Detector

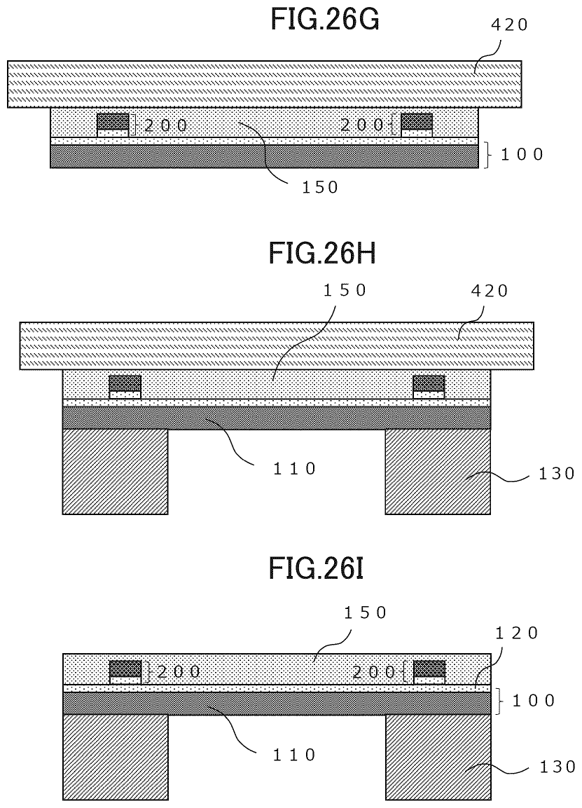

The radiation detector according to the embodiment has a cross-sectional structure as illustrated in FIG. 26I. The present embodiment is different from the first embodiment illustrated in FIG. 1A in that an insulating film 150 is formed so as to cover a wiring layer 120 on which a second semiconductor chip 200 is stacked. That is, the insulating film 150 in which the second semiconductor chip 200 is embedded is provided.

### Manufacturing Method of Radiation Detector

A manufacturing method of the radiation detector according to the present embodiment will be described. FIGS. 24A to 26I to be referred to below are schematic cross-sectional views for describing each stage of a manufacturing process.

First, in a manufacturing process (A) illustrated in FIG. 24A, a semiconductor element such as a MOS transistor is formed in a semiconductor wafer 1110, and the wiring layer 120 is formed on the semiconductor wafer 1110. The semiconductor wafer 1110 is a portion that becomes the semiconductor layer 110 through thinning processing later. A broken line D indicates a position where division in units of chips is to be performed in a subsequent manufacturing process.

In a manufacturing process (B) illustrated in FIG. 24B, the second semiconductor chip 200 adheres to a surface of the wiring layer 120 formed on the semiconductor wafer 1110.

In a manufacturing process (C) illustrated in FIG. 24C, the insulating film 150 such as silicon oxide is formed on the wiring layer 120 to which the second semiconductor chip 200 is attached, and the second semiconductor chip 200 is embedded in the insulating film 150. Then, the insulating film 150 is planarized by back grinding and chemical mechanical polishing (CMP).

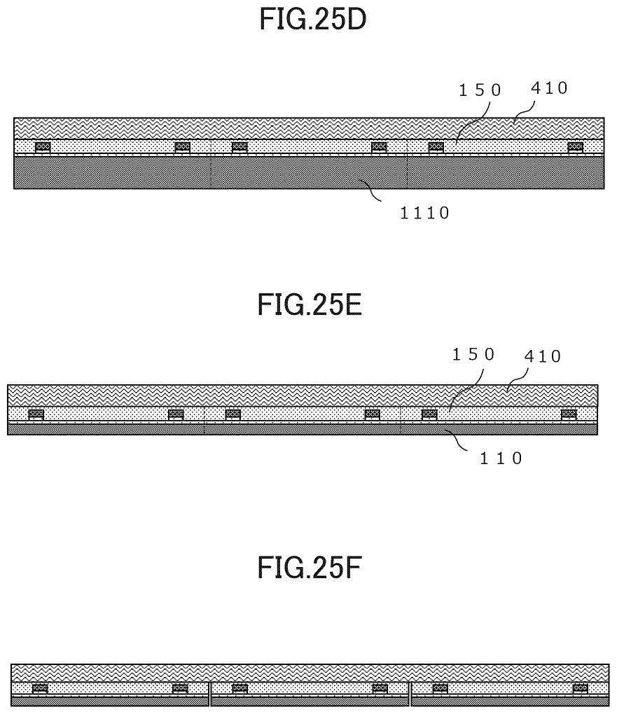

In a manufacturing process (D) illustrated in FIG. 25D, a back grinding tape 410 adheres to the insulating film 150.

In a manufacturing process (E) illustrated in FIG. 25E, the semiconductor wafer 1110 is thinned to a predetermined thickness by back grinding to form the semiconductor layer 110.

In a manufacturing process (F) illustrated in FIG. 25F, a stacked body of the semiconductor layer 110, the wiring layer 120, the second semiconductor chip 200, and the insulating film 150 is diced so as to be divided in units of chips.

In a manufacturing process (G) illustrated in FIG. 26G, one chip obtained by division in units of chips, that is, a first semiconductor chip 100 on which the second semiconductor chip 200 is stacked, is removed from the back grinding tape 410. Then, the insulating film 150 is adhered and fixed to the chip fixing tape 420.

In a manufacturing process (H) illustrated in FIG. 26H, a support portion 130 is attached to the semiconductor layer 110 by an adhesive member.

In a manufacturing process (I) illustrated in FIG. 26I, the chip fixing tape 420 is removed from the first semiconductor chip 100 on which the second semiconductor chip 200 is stacked. In this way, the radiation detector according to the present embodiment can be manufactured.

As described above, the present embodiment and the first embodiment are different from each other in a process of stacking the second semiconductor chip 200. In the present embodiment, since the second semiconductor chip 200 is stacked while the first semiconductor chip 100 is in a state of the semiconductor wafer 1110, a throughput in a mounting process is increased.

In addition, since the second semiconductor chip 200 is embedded in the insulating film 150 and a surface of the insulating film 150 is planarized, the semiconductor wafer 1110 can be fixed to the back grinding tape 410 and can be easily thinned. The present embodiment has been described as a modified example of the first embodiment, but may also be implemented as modified examples of other embodiments.

### Twelfth Embodiment

In the above description, the configuration of the radiation detector has been described as an example of the embodiment. In the present embodiment, a radiation imaging system as an example of a detection system including the above-described radiation detector will be described.

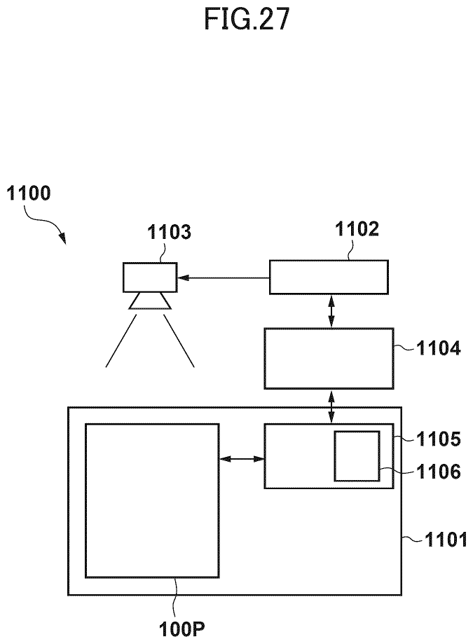

A radiation imaging system 1100 illustrated in FIG. 27 is a detection system including an imaging unit 1101 serving as the radiation detector, an exposure control unit 1102, a radiation source 1103 serving as a radiation application unit, and a computer 1104. The imaging unit 1101 includes an imaging panel 100P including a pixel array. The imaging panel 100P may be any one of the radiation detectors described in the first to eleventh embodiments or a modified example thereof.

The radiation source 1103 starts application of radiation according to an exposure command from the exposure control unit 1102. The radiation extracted from the radiation source 1103 passes through an imaging target (subject) and is injected to the imaging panel 100P of the imaging unit 1101. The radiation source 1103 stops extraction of the radiation according to a stop command from the exposure control unit 1102.

The imaging unit 1101 is, for example, a flat panel detector used for radiography in medical image diagnosis, non-destructive inspection, or the like. The imaging panel 100P of the imaging unit 1101 can have a plate shape whose size corresponds to a size of the imaging target. For example, in the imaging panel 100P, 3300×2800 pixels are arranged on a substrate of 550 mm×445 mm. The imaging unit 1101 may have a direct conversion type configuration that converts radiation into signal charges by a detection diode provided in the pixel array of the imaging panel 100P.

The imaging unit 1101 includes the above-described imaging panel 100P, a control unit 1105 for controlling the imaging panel 100P, and a signal processing unit 1106 for processing a signal output from the imaging panel 100P. For example, the signal processing unit 1106 may perform A/D conversion on a signal output from the imaging panel 100P and output the converted signal as digital image data to the computer 1104. Furthermore, the signal processing unit 1106 may generate a stop signal for stopping application of radiation from the radiation source 1103 based on a signal output from the imaging panel 100P, for example. The stop signal is supplied to the exposure control unit 1102 via the computer 1104, and the exposure control unit 1102 transmits the stop command to the radiation source 1103 in response to the stop signal.

The control unit 1105 can be implemented by, for example, a programmable logic device (PLD) such as a field programmable gate array (FPGA), an application specific integrated circuit (ASIC), a general-purpose computer in which a program is incorporated, or a combination of all or some thereof.

In the present embodiment, the signal processing unit 1106 is illustrated as being disposed in the control unit 1105 or being a part of the function of the control unit 1105, but the signal processing unit 1106 is not limited thereto. The control unit 1105 and the signal processing unit 1106 may be configured separately. Furthermore, the signal processing unit 1106 may be disposed separately from the imaging unit 1101. For example, the computer 1104 may have the function of the signal processing unit 1106. Therefore, the signal processing unit 1106 can be included in the radiation imaging system 1100 as a signal processing device that processes a signal output from the imaging unit 1101.

The computer 1104 can perform control of the imaging unit 1101 and the exposure control unit 1102, and processing for receiving radiation image data from the imaging unit 1101 and displaying the radiation image data as a radiation image. Furthermore, the computer 1104 may function as an input unit for a user to input conditions for capturing a radiation image.

As an example, the exposure control unit 1102 includes an exposure switch, and when the exposure switch is turned on by the user, the exposure control unit 1102 sends an exposure command to the radiation source 1103 and also sends a start notification indicating the start of extraction of radiation to the computer 1104. The computer 1104 receiving the start notification notifies the control unit 1105 of the imaging unit 1101 of the start of application of radiation in response to the start notification. In response to the notification, the control unit 1105 controls the imaging panel 100P to generate a signal corresponding to the injected radiation.

### Thirteenth Embodiment

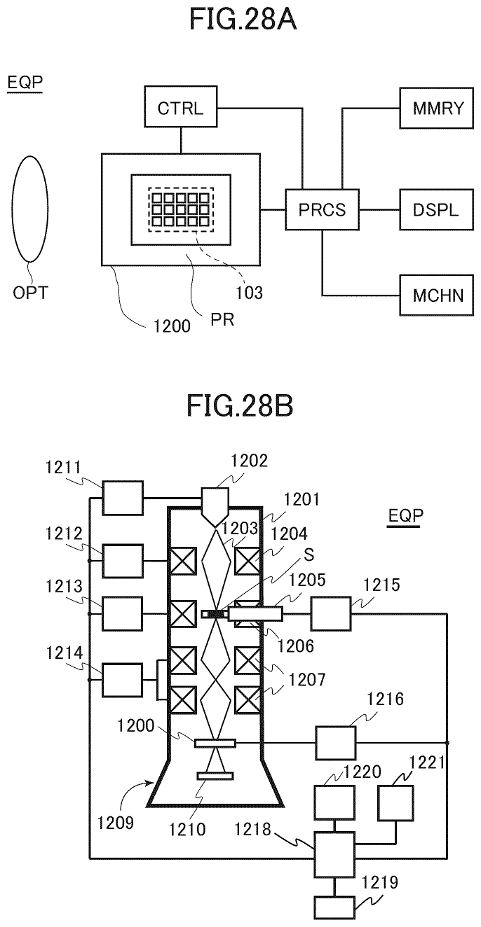

In the present embodiment, another example of the detection system including any one of the radiation detectors according to the first to eleventh embodiments will be described. FIG. 28A illustrates equipment EQP serving as a detection system including a radiation detector 1200 which is one of the radiation detectors described in the first to eleventh embodiments or a modified example thereof.

The radiation detector 1200 includes a pixel array 103 in which pixels are arranged in a matrix and a peripheral region PR around the pixel array. A peripheral circuit (for example, a vertical scanning circuit or a column circuit unit) can be provided in the peripheral region PR.

The equipment EQP can further include at least one of an optical system OPT, a control apparatus CTRL, a processing apparatus PRCS, a display apparatus DSPL, a storage apparatus MMRY, and a mechanical apparatus MCHN. The optical system OPT forms an image of radiation on the radiation detector 1200, and is, for example, a lens, a shutter, or a mirror. The optical system OPT may form an image of a particle beam such as an electron beam or a proton beam on the radiation detector 1200 according to a type of radiation to be handled. The control apparatus CTRL controls the radiation detector 1200, and is, for example, an ASIC. The processing apparatus PRCS processes a signal output from the radiation detector 1200, and is an apparatus such as a central processing unit (CPU) or an ASIC for configuring an analog front end (AFE) or a digital front end (DFE). The display apparatus DSPL is an electroluminescence (EL) display apparatus or a liquid crystal display apparatus for displaying information obtained by the radiation detector 1200 in a form of a visible image or the like. The storage apparatus MMRY is a magnetic device or a semiconductor device that stores information obtained by the radiation detector 1200. The storage apparatus MMRY is a volatile memory such as a static random-access memory (SRAM) or a dynamic random-access memory (DRAM), or a nonvolatile memory such as a flash memory or a hard disk drive. The mechanical apparatus MCHN includes a movable unit such as a motor or an engine, or a propulsion unit.

The equipment EQP displays a signal output from the radiation detector 1200 on the display apparatus DSPL or transmits the signal to the outside by a communication apparatus (not illustrated) included in the equipment EQP. Therefore, the equipment EQP preferably further includes the storage apparatus MMRY and the processing apparatus PRCS separately from a storage circuit and an arithmetic circuit of the radiation detector 1200. The mechanical apparatus MCHN may be controlled based on a signal output from the radiation detector 1200. The equipment EQP illustrated in FIG. 28A may be medical equipment such as an endoscope or radiodiagnosis equipment, measurement equipment such as a distance measurement sensor, or analytical equipment such as an electron microscope.

FIG. 28B is a schematic diagram illustrating a configuration of a transmission electron microscope (TEM) as an example of the equipment EQP. The equipment EQP serving as an electron microscope includes an electron beam source 1202 (electron gun) serving as a radiation (electron beam) application unit, an application lens 1204, a vacuum chamber 1201 (lens barrel), an objective lens 1206, and a magnifying lens system 1207. Further, the equipment EQP includes a camera 1209 serving as an imaging unit. The camera 1209 includes the direct-detection type radiation detector 1200.

The electron beam 1203, which is radiation emitted from the electron beam source 1202, is focused by the application lens 1204 and is applied to a sample S serving as an analysis target held by a sample holder. A space through which the electron beam 1203 passes is formed by the vacuum chamber 1201 (lens barrel), and the space is held in vacuum. The radiation detector 1200 is disposed to face the vacuum space through which the electron beam 1203 passes. The electron beam 1203 transmitted through the sample S is enlarged by the objective lens 1206 and the magnifying lens system 1207 and projected onto the radiation detector 1200. An electron optical system for applying the electron beam to the sample S is referred to as an application optical system, and an electron optical system for forming an image of the electron beam transmitted through the sample S on the radiation detector 1200 is referred to as an imaging optical system.

The electron beam source 1202 is controlled by an electron beam source control apparatus 1211. The application lens 1204 is controlled by an application lens control apparatus 1212. The objective lens 1206 is controlled by an objective lens control apparatus 1213. The magnifying lens system 1207 is controlled by a magnifying lens system control apparatus 1214. A control mechanism 1205 of the sample holder is controlled by a holder control apparatus 1215 that controls a drive mechanism of the sample holder.

The electron beam 1203 transmitted through the sample S is detected by the radiation detector 1200 of the camera 1209. An output signal from the radiation detector 1200 is processed by a signal processing apparatus 1216 and an image processing apparatus 1218 serving as the processing apparatuses PRCS to generate an image signal. The generated image signal (transmitted electron image) is displayed on an image display monitor 1220 and an analysis monitor 1221 corresponding to the display apparatus DSPL.

The camera 1209 is provided at the bottom of the equipment EQP. The camera 1209 includes the radiation detector 1200 that directly converts an electron beam into a charge signal. The radiation detector 1200 corresponds to an imaging element. The radiation detector 1200 is provided in the camera 1209 such that at least a part of the camera 1209 is exposed to the vacuum space formed by the vacuum chamber 1201. The electron beam 1203 transmitted through the radiation detector 1200 is absorbed by an electron beam absorbing member 1210. The camera 1209 can also be detachable from the vacuum chamber 1201. In a case where the radiation detector 1200 needs to be replaced, the camera 1209 can be removed from the vacuum chamber 1201 and can be replaced with a new one. In order to replace the camera 1209 without breaking the vacuum of the vacuum chamber 1201, an openable and closable vacuum partition wall may be provided between the camera 1209 and the vacuum chamber 1201.

Each of the electron beam source control apparatus 1211, the application lens control apparatus 1212, the objective lens control apparatus 1213, the magnifying lens system control apparatus 1214, and the holder control apparatus 1215 is connected to the image processing apparatus 1218. As a result, data can be exchanged with each other in order to set imaging conditions of the electron microscope. In this case, the electron beam source control apparatus 1211 and the image processing apparatus 1218 function as a control unit that controls a radiation application rate. Drive control of the sample holder and observation conditions of each lens can be set by a signal from the image processing apparatus 1218. An operator prepares the sample S to be imaged, and sets imaging conditions by using an input apparatus 1219 connected to the image processing apparatus 1218. Predetermined data is input to each of the electron beam source control apparatus 1211, the application lens control apparatus 1212, the objective lens control apparatus 1213, and the magnifying lens system control apparatus 1214, and a desired acceleration voltage, magnification, and observation mode are obtained. In addition, the operator inputs conditions such as the number of consecutive visual field images, an imaging start position, and a movement speed of the sample holder to the image processing apparatus 1218 by using the input apparatus 1219 such as a mouse, a keyboard, or a touch panel. Alternatively, the image processing apparatus 1218 may automatically set the conditions without depending on the operator's input.

The detection systems described in the twelfth embodiment and the thirteenth embodiment above are merely examples, and the radiation detectors described in the first to eleventh embodiments or radiation detectors obtained by modifying the radiation detectors may be applied to another detection system.

The present disclosure is not limited to the embodiments described above, and many modifications can be made within the technical idea of the present disclosure. For example, all or some of the different embodiments described above may be combined and implemented.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-217046,filed Dec. 11, 2024, which is hereby incorporated by reference herein in its entirety.

What is claimed is:

1. A radiation detector comprising:
a first semiconductor chip including a detection region and a peripheral region positioned around the detection region in plan view;
a support portion disposed in the peripheral region so as not to overlap the detection region in plan view; and
a second semiconductor chip disposed in the peripheral region,
wherein in plan view, an end portion of the support portion, which is positioned on a side closer to the detection region among end portions of the support portion, is disposed closer to the detection region than an end portion of the second semiconductor chip, which is positioned on a side closer to an outer edge of the first semiconductor chip among end portions of the second semiconductor chip.

2. The radiation detector according to claim 1, wherein
in plan view, an end portion of the support portion, which is positioned on a side opposite to the detection region among the end portions of the support portion, is positioned farther from the detection region than an end portion of the second semiconductor chip, which is positioned on a side closer to the detection region among the end portions of the second semiconductor chip, and
the support portion is disposed on a surface of the first semiconductor chip, which is opposite to a surface on which the second semiconductor chip is disposed.

3. The radiation detector according to claim 1, wherein
in plan view, an end portion of the support portion, which is positioned on a side opposite to the detection region among the end portions of the support portion, is positioned farther from the detection region than an end portion of the second semiconductor chip, which is positioned on a side closer to the detection region among the end portions of the second semiconductor chip,
the second semiconductor chip and the support portion are disposed on the same surface of the first semiconductor chip, and
the support portion includes a recess for fitting to the second semiconductor chip.

4. The radiation detector according to claim 1, wherein
in plan view, an end portion of the support portion, which is positioned on a side opposite to the detection region among the end portions of the support portion, is positioned closer to the detection region than an end portion of the second semiconductor chip, which is positioned on a side closer to the detection region among the end portions of the second semiconductor chip, and
the support portion is disposed on a surface of the first semiconductor chip, which is opposite to a surface on which the second semiconductor chip is disposed.

5. The radiation detector according to claim 1, wherein
in plan view, an end portion of the support portion, which is positioned on a side opposite to the detection region among the end portions of the support portion, is positioned closer to the detection region than an end portion of the second semiconductor chip, which is positioned on a side closer to the detection region among the end portions of the second semiconductor chip, and
the second semiconductor chip and the support portion are disposed on the same surface of the first semiconductor chip.

6. The radiation detector according to claim 1, wherein
the first semiconductor chip includes a semiconductor layer and a wiring layer, and
the wiring layer includes a heat dissipation wiring at a position overlapping at least one of the second semiconductor chip and the support portion in plan view.

7. The radiation detector according to claim 6, wherein the heat dissipation wiring includes a plurality of conductor layers and a via plug configured to connect the plurality of conductor layers to each other.

8. The radiation detector according to claim 6, further comprising a via plug configured to connect the heat dissipation wiring to the semiconductor layer.

9. The radiation detector according to claim 6, wherein
the second semiconductor chip includes a semiconductor layer and a wiring layer, and
the heat dissipation wiring is connected to the wiring layer of the second semiconductor chip.

10. The radiation detector according to claim 9, wherein the heat dissipation wiring is connected to the semiconductor layer of the first semiconductor chip on a side closer to an outer edge of the first semiconductor chip than the second semiconductor chip.

11. The radiation detector according to claim 1, further comprising:
an attachment substrate that is in contact with the support portion; and
a cooling mechanism configured to cool the attachment substrate.

12. The radiation detector according to claim 1, wherein the first semiconductor chip includes a semiconductor layer, a wiring layer, and a support substrate bonded to the wiring layer.

13. The radiation detector according to claim 1, wherein
each of the first semiconductor chip and the second semiconductor chip includes a wiring layer, and
the wiring layer included in the first semiconductor chip and the wiring layer included in the second semiconductor chip are disposed to face each other.

14. The radiation detector according to claim 1, further comprising a Cu—Cu hybrid bonding structure configured to connect the first semiconductor chip and the second semiconductor chip to each other.

15. The radiation detector according to claim 1, wherein
the second semiconductor chip is one of a plurality of second semiconductor chips disposed in the peripheral region, and
the plurality of second semiconductor chips include a second semiconductor chip disposed along a first side of the first semiconductor chip, and a second semiconductor chip disposed along a second side of the first semiconductor chip, the second side facing the first side with the detection region interposed therebetween in plan view.

16. The radiation detector according to claim 1, wherein
the second semiconductor chip is one of a plurality of second semiconductor chips disposed in the peripheral region, and
the plurality of second semiconductor chips include a second semiconductor chip disposed along a first side of the first semiconductor chip, and a second semiconductor chip disposed along a second side of the first semiconductor chip, the second side intersecting the first side in plan view.

17. The radiation detector according to claim 1, wherein
the second semiconductor chip is one of a plurality of second semiconductor chips disposed in the peripheral region, and
the plurality of second semiconductor chips include at least two second semiconductor chips disposed along one side of the first semiconductor chip.

18. The radiation detector according to claim 1, wherein
the first semiconductor chip includes a buffer region between the detection region and the peripheral region in plan view, and
at least a part of the support portion is disposed in the buffer region in plan view.

19. The radiation detector according to claim 1, further comprising an insulating film in which the second semiconductor chip is embedded.

20. A radiation imaging system comprising:
a radiation source configured to apply radiation to an imaging target; and
the radiation detector according to claim 1.
